(19) United States
(12) Patent Application Publication
(10) Pub. No.: US 2023/0191449 A1
(43) Pub. Date: Jun. 22, 2023

(54) Substrate Processing Apparatus, Substrate Processing Method, Method of Manufacturing Semiconductor Device and Non-transitory Computer-readable Recording Medium

(71) Applicant: Kokusai Electric Corporation, Tokyo (JP)

(72) Inventor: Satoshi TAKANO, Toyama (JP)

(21) Appl. No.: 17/696,612

(22) Filed: Mar. 16, 2022

(30) Foreign Application Priority Data
Dec. 22, 2021 (JP) 2021-208693

(51) Int. Cl. H01L 21/67; H01L 21/677; H01L 21/68

(52) U.S. Cl. CPC H01L 21/67063; H01L 21/67742; H01L 21/68

(57) ABSTRACT

A technique capable of suppressing a displacement of a substrate with respect to a mounting table when transferring the substrate by rotating an arm and placing the substrate transferred by the arm on the mounting table is provided. According to one aspect thereof, there is provided a substrate processing apparatus including: a transfer device including: a shaft; and an arm extending from the shaft, wherein the transfer device transferring a substrate to a location above a mounting table by rotating the arm supporting the substrate; a detector configured to detect the substrate; a transfer controller controlling the transfer device to detect a transfer displacement of the substrate with respect to the arm based on a result detected by the detector and to correct a positional displacement of the substrate with respect to the mounting table; and a processing structure in which a process with respect to the substrate is performed.

### CROSS REFERENCE TO RELATED APPLICATIONS

This application claims foreign priority under 35 U.S.C. § 119(a)-(d) to Application No. JP 2021-208693 filed on Dec. 22, 2021, the entire contents of which are hereby incorporated by reference.

### TECHNICAL FIELD

The present disclosure relates to a substrate processing apparatus, a substrate processing method, a method of manufacturing a semiconductor device and a non-transitory computer-readable recording medium.

### BACKGROUND

A substrate processing apparatus according to some related arts may include a transfer structure configured to transfer a substrate into and out of a process chamber and a controller configured to control the transfer structure in accordance with an automatic transfer process including a substrate transfer sequence constituted by a plurality of sequences. Further, a sequence such as the substrate transfer sequence may include a transfer operation executed when each transfer is performed and a determination step of checking each transfer operation by a sensor.

According to a conventional substrate processing apparatus, the transfer operation for the substrate transferred from a vacuum apparatus to the process chamber may be checked. In other words, the transfer operation for the substrate transferred from a component to another component may be checked. However, in such a configuration, it may not be possible to check an operation of the substrate transferred inside each component.

For example, inside the component, a configuration in which the substrate is supported by an arm, the substrate is transferred by rotating the arm, and the substrate transferred by rotating the arm is placed on a mounting table. In such a configuration, when the arm is rotated, the substrate supported by the arm may be dislocated with respect to the arm. When the substrate transferred by the arm is placed on the mounting table in such a case, the substrate placed on the mounting table may be displaced.

### SUMMARY

According to the present disclosure, there is provided a technique capable of suppressing a displacement of a substrate with respect to a mounting table when transferring the substrate by rotating an arm and placing the substrate transferred by the arm on the mounting table.

According to one aspect of the technique of the present disclosure, there is provided a substrate processing apparatus including: a transfer device including: a shaft configured to be rotated about a vertical direction as an axial direction; and an arm extending in a horizontal direction from the shaft and configured to support a substrate, wherein the transfer device is configured to transfer the substrate to a location above a mounting table by rotating the arm supporting the substrate; a detector configured to detect the substrate supported and transferred by the arm; a transfer controller configured to be capable of controlling the transfer device so as to detect a transfer displacement of the substrate with respect to the arm based on a result detected by the detector and to correct a positional displacement of the substrate with respect to the mounting table; and a processing structure in which a process with respect to the substrate placed on the mounting table is performed.

### BRIEF DESCRIPTION OF THE DRAWINGS

FIG. 1 is a diagram schematically illustrating an overall configuration of a substrate processing apparatus according to one or more embodiments of the present disclosure.

FIG. 2 is a diagram schematically illustrating a cross-section of a process furnace and related components provided in the substrate processing apparatus according to the embodiments of the present disclosure.

FIG. 3 is a block diagram schematically illustrating a process controller and related components provided in the substrate processing apparatus according to the embodiments of the present disclosure.

FIG. 4 is a flow chart schematically illustrating each step of a film-forming process performed by the process controller of the substrate processing apparatus according to the embodiments of the present disclosure.

FIG. 5 is a diagram schematically illustrating a susceptor and related components provided in a process module of the substrate processing apparatus according to the embodiments of the present disclosure.

FIG. 6 is a block diagram schematically illustrating a transfer controller and related components provided in the substrate processing apparatus according to the embodiments of the present disclosure.

FIG. 7A is a diagram schematically illustrating a step performed by the transfer controller of the substrate processing apparatus according to the embodiments of the present disclosure, and more specifically, schematically illustrating a state in which a wafer is arranged on the susceptor provided at a front side.

FIG. 7B is a diagram schematically illustrating a step performed by the transfer controller of the substrate processing apparatus according to the embodiments of the present disclosure, and more specifically, schematically illustrating a state in which an arm is inserted between the susceptor and the wafer.

FIG. 7C is a diagram schematically illustrating a step performed by the transfer controller of the substrate processing apparatus according to the embodiments of the present disclosure, and more specifically, schematically illustrating a state in which the wafer is supported by the arm.

FIG. 7D is a diagram schematically illustrating a step performed by the transfer controller of the substrate processing apparatus according to the embodiments of the present disclosure, and more specifically, schematically illustrating a state in which the wafer supported by the arm is transferred.

FIG. 7E is a diagram schematically illustrating a step performed by the transfer controller of the substrate processing apparatus according to the embodiments of the present disclosure, and more specifically, schematically illustrating a state in which the wafer is supported by pins.

FIG. 7F is a diagram schematically illustrating a step performed by the transfer controller of the substrate processing apparatus according to the embodiments of the present disclosure, and more specifically, schematically illustrating a state in which the arm is rotated by a displacement amount of the wafer.

FIG. 7G is a diagram schematically illustrating a step performed by the transfer controller of the substrate processing apparatus according to the embodiments of the present disclosure, and more specifically, schematically illustrating a state in which the wafer is supported by the arm and the arm is rotated in an opposite direction by the displacement amount.

FIG. 7H is a diagram schematically illustrating a step performed by the transfer controller of the substrate processing apparatus according to the embodiments of the present disclosure, and more specifically, schematically illustrating a state in which a displacement of each wafer is corrected.

FIG. 7I is a diagram schematically illustrating a step performed by the transfer controller of the substrate processing apparatus according to the embodiments of the present disclosure, and more specifically, schematically illustrating a state in which the pins support the wafer.

FIG. 7J is a diagram schematically illustrating a step performed by the transfer controller of the substrate processing apparatus according to the embodiments of the present disclosure, and more specifically, schematically illustrating a state in which the wafer is arranged on the susceptor provided at the front side.

FIG. 7K is a diagram schematically illustrating a step performed by the transfer controller of the substrate processing apparatus according to the embodiments of the present disclosure, and more specifically, schematically illustrating a state in which the arm is moved to an initial position.

FIG. 8A is a diagram schematically illustrating a step performed by the transfer controller of the substrate processing apparatus according to the embodiments of the present disclosure, and more specifically, schematically illustrating a state in which the arm supports the wafer on which the film-forming process is performed.

FIG. 8B is a diagram schematically illustrating a step performed by the transfer controller of the substrate processing apparatus according to the embodiments of the present disclosure, and more specifically, schematically illustrating a state in which the pins support the wafer on which the film-forming process is performed.

FIG. 8C is a diagram schematically illustrating a step performed by the transfer controller of the substrate processing apparatus according to the embodiments of the present disclosure, and more specifically, schematically illustrating a state in which the wafer arranged on the susceptor provided at the front side is taken out.

FIG. 8D is a diagram schematically illustrating a step performed by the transfer controller of the substrate processing apparatus according to the embodiments of the present disclosure, and more specifically, schematically illustrating a state in which the wafer arranged on the susceptor provided at a back side is transferred to the susceptor provided at the front side.

FIG. 8E is a diagram schematically illustrating a step performed by the transfer controller of the substrate processing apparatus according to the embodiments of the present disclosure, and more specifically, schematically illustrating a state in which the wafer arranged on the susceptor provided at the front side is taken out.

FIG. 8F is a diagram schematically illustrating a step performed by the transfer controller of the substrate processing apparatus according to the embodiments of the present disclosure, and more specifically, schematically illustrating a state in which the arm is moved to the initial position.

FIG. 9A is a flow chart schematically illustrating each step of a transfer process performed by the process controller of the substrate processing apparatus according to the embodiments of the present disclosure.

FIG. 9B is a flow chart schematically illustrating each step of the transfer process performed by the process controller of the substrate processing apparatus according to the embodiments of the present disclosure.

FIG. 9C is a flow chart schematically illustrating each step of the transfer process performed by the process controller of the substrate processing apparatus according to the embodiments of the present disclosure.

### DETAILED DESCRIPTION

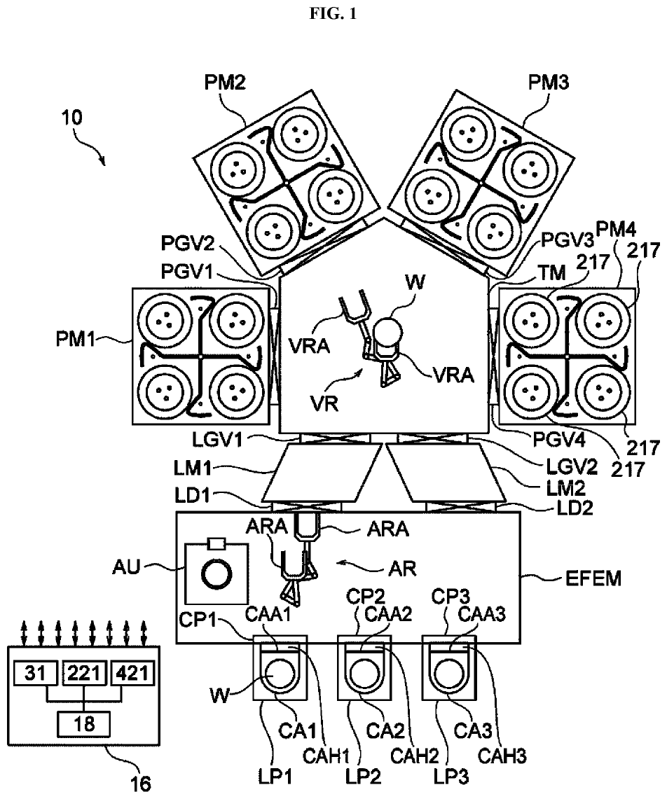

Hereinafter, a substrate processing apparatus, a substrate processing method, a method of manufacturing a semiconductor device and a non-transitory computer-readable recording medium according to one or more embodiments (also simply referred to as “embodiments”) of the technique of the present disclosure will be described with reference to FIGS. 1 through 9C. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### Overall Configuration of Substrate Processing Apparatus

A substrate processing apparatus 10 shown in FIG. 1 includes a vacuum side configuration of handling a substrate (for example, a wafer W made of a material such as silicon) in a reduced pressure state and an atmospheric pressure side configuration of handling the wafer W in an atmospheric pressure state. The vacuum side configuration mainly includes a vacuum transfer chamber TM, load lock chambers LM1 and LM2 and process modules (which are processing configurations) PM1, PM2, PM3 and PM4 capable of processing the wafer W serving as the substrate. The atmospheric pressure side configuration mainly includes an atmospheric pressure transfer chamber EFEM and loading port structures LP1, LP2 and LP3.

Carriers CA1, CA2 and CA3 capable of accommodating a plurality of wafers including the wafer W are transferred and placed on the loading port structures LP1 through LP3, respectively, from an outside of the substrate processing apparatus 10, and are also transferred to the outside of the substrate processing apparatus 10 from the loading port structures LP1 through LP3, respectively. Hereinafter, the plurality of wafers including the wafer W may also be simply referred to as “wafers W”. As a result, for example, the wafer W (which is unprocessed) is taken out from the carrier CA1 placed on the loading port structure LP1, is loaded (transferred) into the process module PM1 through the load lock chamber LM1 and processed in the process module PM1. Then, the wafer W (which is processed) is returned to the carrier CA1 on the loading port structure LP1 in an order reverse to that described above.

### Vacuum Side Configuration

The vacuum transfer chamber TM is configured as a vacuum airtight structure capable of withstanding a negative pressure (which is a reduced pressure) below an atmospheric pressure such as a pressure in a vacuum state. Further, according to the present embodiments, for example, a housing of the vacuum transfer chamber TM is pentagonal when viewed from above. The housing is of a box shape with closed upper and lower ends in a vertical direction.

The load lock chambers LM1 and LM2 and the process modules PM1 through PM4 are arranged so as to surround an outer periphery of the vacuum transfer chamber TM. In the present specification, unless the process modules PM1 through PM4 need to be distinguished separately, the process modules PM1 through PM4 may be collectively or individually referred to as a “process module PM”. In addition, unless the load lock chambers LM1 and LM2 need to be distinguished separately, the load lock chambers LM1 and LM2 may be collectively or individually referred to as a “load lock chambers LM”. The same also applies to other configurations such as a vacuum robot VR and an arm VRA, which will be described later.

The vacuum robot VR is provided in the vacuum transfer chamber TM. The vacuum robot VR serves as a transfer structure (which is a transfer system or a transfer robot) capable of transferring the wafer W in the reduced pressure state. The vacuum robot VR is configured to transfer the wafer W between the load lock chamber LM and the process module PM by placing the wafer W on two sets of substrate support arms VRA (hereinafter, may also be referred to as the “arm VRA”). Further, the vacuum robot VR is configured to be elevated or lowered in the vertical direction while maintaining an airtightness of the vacuum transfer chamber TM. In addition, the two sets of the arm VRA are separated in the vertical direction. Each of the two sets of the arm VRA is configured to be capable of being expanded and contracted in a horizontal direction and being rotationally moved in a horizontal plane. The vacuum robot VR serves as an example of an arrangement structure (which is an arrangement system or an arrangement robot).

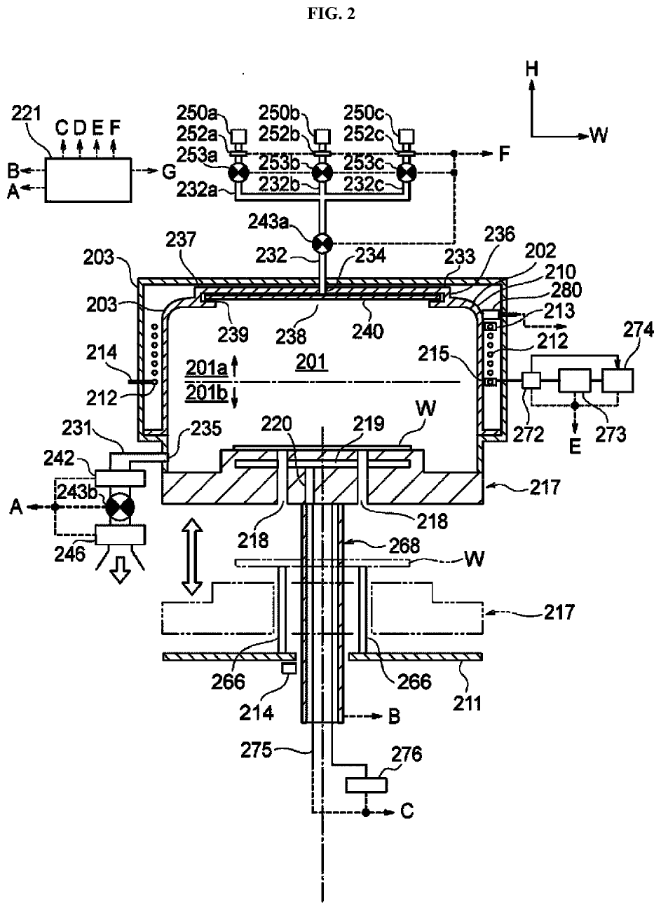

For example, each process module PM includes four susceptors 217 on which the wafer W is placed and four process chambers 201 (see FIG. 2) in which the wafer W placed on each of the susceptors 217 is processed in the reduced pressure state. That is, each process module PM includes the four process chambers 201 in which processes (for example, an etching process using a plasma or the like, an ashing process and a film-forming process by a chemical reaction) are performed to the wafer W to provide added values to the wafer W. Each of the susceptors 217 serves as an example of a mounting table. Hereinafter, the four process chambers 201 may also be collectively or individually referred to as a “process chamber 201”, and the four susceptors 217 may also be collectively or individually referred to as a “susceptor 217”.

The process module PM is connected to the vacuum transfer chamber TM by a gate valve PGV serving as an opening/closing valve. As a result, the process module PM can transfer the wafer W to and from the vacuum transfer chamber TM under the reduced pressure by opening the gate valve PGV. Further, by closing the gate valve PGV, the process module PM can perform various processes such as a substrate processing on the wafer W while maintaining an inner pressure of the process module PM to a desired pressure and an inner atmosphere of the process module PM to a process gas atmosphere.

The load lock chamber LM functions as a spare chamber for transferring the wafer W into the vacuum transfer chamber TM or as a spare chamber for transferring the wafer W out of the vacuum transfer chamber TM. Buffer stages (not shown) configured to temporarily support the wafer W when the wafer W is transferred into or out of the vacuum transfer chamber TM are provided in the load lock chamber LM. Each of the buffer stages may be configured as a multi-stage type slot capable of supporting a predetermined number of wafers (for example, two wafers) including the wafer W.

Further, the load lock chamber LM is connected to the vacuum transfer chamber TM by a gate valve LGV serving as an opening/closing valve. Further, the load lock chamber LM is connected to the atmospheric pressure transfer chamber EFEM, which will be described later, by a gate valve LD serving as an opening/closing valve. By closing the gate valve LGV provided corresponding to the vacuum transfer chamber TM and opening the gate valve LD provided corresponding to the atmospheric pressure transfer chamber EFEM, it is possible to transfer the wafer W between the load lock chamber LM and the atmospheric pressure transfer chamber EFEM under the atmospheric pressure while maintaining a vacuum airtightness in the vacuum transfer chamber TM.

Further, the load lock chamber LM is configured as a vacuum airtight structure capable of withstanding the negative pressure (which is the reduced pressure) below the atmospheric pressure such as the pressure in the vacuum state, and is configured such that an inner atmosphere of the load lock chamber LM can be vacuum-exhausted. Thereby, after the gate valve LD provided corresponding to the atmospheric pressure transfer chamber EFEM is closed and the inner atmosphere of the load lock chamber LM is vacuum-exhausted, the gate valve LGV provided corresponding to the vacuum transfer chamber TM is opened. As a result, it is possible to transfer the wafer W between the load lock chamber LM and the vacuum transfer chamber TM under the reduced pressure while maintaining the vacuum airtightness (vacuum state) in the vacuum transfer chamber TM.

### Atmospheric Pressure Side Configuration

The atmospheric pressure transfer chamber EFEM (Equipment Front End Module) and the loading port structures LP1 through LP3 serving as a carrier mounting structure on which the carriers CA1 through CA3 can be placed are provided at an atmospheric pressure portion of the substrate processing apparatus 10.

The atmospheric pressure transfer chamber EFEM serves as a front module connected to the load lock chambers LM1 and LM2, and the carriers CA1 through CA3 are connected to the atmospheric pressure transfer chamber EFEM. For example, each of the carriers CA1 through CA3 serves as a wafer storage container in which the wafers W corresponding to a single lot (for example, 25 wafers) can be stored. As each of the carriers CA1 through CA3, for example, a FOUP (Front Opening Unified Pod) may be used.

In the present specification, unless the loading port structures LP1 through LP3 need to be distinguished separately, the loading port structures LP1 through LP3 may be collectively or individually referred to as a “loading port structure LP”. In addition, unless the carriers CA1 through CA3 need to be distinguished separately, the carriers CA1 through CA3 may be collectively or individually referred to as a “carrier CA”. The same also applies to other configurations such as carrier doors CAH1, CAH2 and CAH3 and carrier openers CP1, CP2 and CP3, which will be described later.

For example, an atmospheric pressure robot AR serving as a transfer structure is provided in the atmospheric pressure transfer chamber EFEM. The atmospheric pressure robot AR is configured to transfer the wafer W between the load lock chamber LM1 and the carrier CA on the loading port structure LP1. The atmospheric pressure robot AR is also provided with two sets of arms ARA similar to the vacuum robot VR.

The carrier CA is provided with a carrier door CAH which serves as a cap (lid) of the carrier CA. With the carrier door CAH of the carrier CA installed on the loading port structure LP open, the wafer W may be accommodated in the carrier CA by the atmospheric pressure robot AR through a substrate loading/unloading port CAA, or the wafer W in the carrier CA may be transferred out of the carrier CA by the atmospheric pressure robot AR.

Further, in the atmospheric pressure transfer chamber EFEM, a carrier opener CP capable of opening and closing the carrier door CAH is provided corresponding to the loading port structure LP. That is, the inside of the atmospheric pressure transfer chamber EFEM is connected to the loading port structure LP via the carrier opener CP. The carrier opener CP is configured to open and close the carrier door CAH by moving in the horizontal direction and the vertical direction together with the carrier door CAH while in close contact with the carrier door CAH.

Further, in the atmospheric pressure transfer chamber EFEM, an aligner AU, which is an orientation flat alignment device capable of aligning a crystal orientation of the wafer W, is provided as a substrate position correction device. In addition, the atmospheric pressure transfer chamber EFEM is provided with a clean air supplier (which is a clean air supply structure or a clean air supply system) (not shown) through which clean air is supplied into the atmospheric pressure transfer chamber EFEM.

The loading port structure LP is configured to place the carrier CA accommodating the plurality of wafers W on the loading port structure LP. In each carrier CA, slots (not shown) serving as a storage structure capable of accommodating the wafers W are provided. For example, 25 slots corresponding to the single lot are provided. When the carrier CA is placed, each loading port structure LP is configured to read and store a bar code or the like provided at the carrier CA and indicating a carrier ID used to identify the carrier CA.

### Controller 16

The substrate processing apparatus 10 includes a controller (which is a control structure) 16 configured to collectively control the substrate processing apparatus 10. That is, the controller 16 is configured to control each component of the substrate processing apparatus 10. The controller 16 includes an apparatus controller 18 serving as an operation structure, a transfer system controller 31 serving as a transfer control structure, a process controller 221 serving as a processing control structure and a transfer controller 421.

### —Apparatus Controller 18—

The apparatus controller 18 serves as an interface with an operating personnel. Together with an operation display (not shown), the apparatus controller 18 is configured to receive an operation or an instruction by the operating personnel via the operation display. Information such as an operation screen and various data is displayed on the operation display. The data displayed on the operation display is stored in a memory of the apparatus controller 18.

### —Transfer System Controller 31—

The transfer system controller 31 includes a robot controller configured to control the vacuum robot VR and the atmospheric pressure robot AR, and is configured to perform a transfer control of the wafer W and an execution of a work instructed by the operating personnel.

Further, for example, based on a transfer recipe created by the operating personnel via the apparatus controller 18, the transfer system controller 31 is configured to output control data (control instruction) when the wafer W is transferred to the components such the vacuum robot VR, the atmospheric pressure robot AR, various valves and switches. Then, the transfer system controller 31 performs the transfer control of the wafer W inside the substrate processing apparatus 10. The process controller 221 and the transfer controller 421 will be described in detail later.

As shown in FIG. 1, the controller 16 may be provided not only inside the substrate processing apparatus 10 but also outside the substrate processing apparatus 10. Further, the process controller 221 serving as the processing control structure configured to control the apparatus controller 18, the transfer system controller 31 and the process module PM may be embodied by a general purpose computer such as a PC (personal computer). In such a case, each controller may be configured by installing a program on the general purpose computer by using a computer-readable recording medium such as a USB memory and a DVD in which various programs are stored.

Further, a method of supplying the program for executing a processing can be appropriately selected. Instead of or in addition to being supplied through a predetermined recording medium, for example, the program may be provided through a communication line, a communication network or a communication system. In such a case, for example, the program may be posted on a bulletin board on the communication network, and may be provided by being superimposed on a carrier wave via the communication network. Further, the program provided as described above may be executed to perform the above-described processing under control of an OS (operating system) of the substrate processing apparatus 10 just like any other application programs.

### Process Module PM

For example, each process module PM is provided with four process vessels 203. Hereinafter, the four process vessels 203 may also be collectively or individually referred to as a “process vessel 203”. The process vessel 203 is configured such that the wafer W is processed by the plasma in the process vessel 203. As shown in FIG. 2, the process vessel 203 is provided with a process furnace 202 constituting the process chamber 201. The process vessel 203 serves as an example of a processing structure.

### —Process Vessel 203—

The process vessel 203 includes a dome-shaped upper vessel 210 serving as a first vessel and made of a material such as quartz (hereinafter, also referred to as a “quartz dome”. A lower portion of the upper vessel 210 is open. By closing a lower end of the upper vessel 210 by the susceptor 217, the process chamber 201 is defined inside the upper vessel 210.

Further, the upper vessel 210 is provided with a temperature sensor 280 such as a thermocouple such that a temperature of the upper vessel 210 can be detected. For example, the upper vessel 210 is made of a non-metallic material such as aluminum oxide (Al₂O₃) and quartz (SiO₂).

For example, the process chamber 201 includes a plasma generation space 201a (indicated by a portion above a chain line in FIG. 2) and a substrate processing space 201b that communicates with the plasma generation space 201a and in which the wafer W is processed. A resonance coil 212 is provided around the plasma generation space 201a. The plasma generation space 201a refers to a space in which the plasma is generated, for example, a space above a lower end of the resonance coil 212 and below an upper end of the resonance coil 212 in the process chamber 201.

On the other hand, the substrate processing space 201b (indicated by a portion below the chain line in FIG. 2) refers to a space in which the wafer W is processed by the plasma, for example, a space below the lower end of the resonance coil 212. According to the present embodiments, a diameter of the plasma generation space 201a in the horizontal direction is set to be substantially the same as a diameter of the substrate processing space 201b in the horizontal direction.

### —Suceptor 217—

The susceptor 217 serving as a mounting structure on which the wafer W is placed is arranged at a bottom of the process chamber 201. For example, the susceptor 217 is made of a non-metallic material such as aluminum nitride (AlN), ceramics and quartz, and is configured to be capable of reducing a metal contamination on a structure such as a film formed on the wafer W.

A heater 219 serving as a heating structure is integrally embedded in the susceptor 217. When electric power is supplied to the heater 219, the heater 219 is configured to heat a surface of the wafer W placed on the susceptor 217 such that the wafer W is heated to a predetermined temperature within a range from 25° C. to 750° C., for example.

An impedance adjustment electrode 220 is provided in the susceptor 217 so as to further improve a uniformity of a density of the plasma generated on the wafer W placed on the susceptor 217. The impedance adjustment electrode 220 is grounded via a variable impedance regulator 275 serving as an impedance adjusting structure. The variable impedance regulator 275 is constituted by components such as a coil (not shown) and a variable capacitor (not shown). The variable impedance regulator 275 is configured to change an impedance of the impedance adjustment electrode 220 within a predetermined range from about 0Ω to a parasitic impedance value of the process chamber 201 by controlling an inductance and resistance of the coil (not shown) and a capacitance value of the variable capacitor (not shown).

A susceptor elevator 268 configured to elevate and lower the susceptor 217 is provided at the susceptor 217. In addition, through-holes 218 are provided at the susceptor 217. Further, pins 266 are provided such that the pins 266 are inserted into the through-holes 218 and configured to push up the wafer W when the susceptor 217 is moved downward (indicated by a two-dot chain line in FIG. 2). The pins 266 serve as an example of a part of an elevating structure.

The pins 266 are provided at a lower base 211, and the lower base 211 is provided with an elevator 214 capable of elevating and lowering the pins 266 together with the lower base 211.

A configuration of placing the wafers W on each of the four susceptors 217 provided in the process module PM and a process of placing the wafers W on each of the four susceptors 217 will be described later.

### —Gas Supplier—

A gas supply head 236 is provided above the process chamber 201, that is, on an upper portion of the upper vessel 210. The gas supply head 236 includes a cap-shaped lid 233, a gas inlet port 234, a buffer chamber 237, an opening 238, a shield plate 240 and a gas outlet port 239. In addition, the gas supply head 236 is configured such that a gas such as a reactive gas can be supplied into the process chamber 201 through the gas supply head 236. The buffer chamber 237 functions as a dispersion space in which the reactive gas introduced (supplied) through the gas inlet port 234 is dispersed.

A gas supply pipe 232 is connected to the gas inlet port 234. A downstream end of an oxygen-containing gas supply pipe 232a through which an oxygen-containing gas is supplied, a downstream end of a hydrogen-containing gas supply pipe 232b through which a hydrogen-containing gas is supplied and a downstream end of an inert gas supply pipe 232c through which an inert gas is supplied are connected to join the gas supply pipe 232. For example, as the oxygen-containing gas, a gas such as oxygen (O₂) gas, ozone (O₃) gas, a mixed gas of the O₂ gas and hydrogen (H₂) gas, water vapor (H₂O gas), hydrogen peroxide (H₂O₂) gas, nitrous oxide (N₂O) gas, nitrogen monoxide (NO) gas, nitrogen dioxide (NO₂) gas, carbon monoxide (CO) gas and carbon dioxide (CO₂) gas may be used. Further, as the oxygen-containing gas, one or more of the gases described above may be used. In addition, for example, as the hydrogen-containing gas, a gas such as the H₂ gas, the H₂O gas, H₂O₂ gas, deuterium (D₂) gas may be used. Further, as the hydrogen-containing gas, one or more of the gases described above may be used. For example, as the inert gas, a gas such as nitrogen (N₂) gas and a rare gas such as argon (Ar) gas, helium (He) gas, neon (Ne) gas and xenon (Xe) gas may be used. Further, as the inert gas, one or more of the gases described above may be used.

An oxygen-containing gas supply source 250a, a mass flow controller (MFC) 252a serving as a flow rate controller and a valve 253a serving as an opening/closing valve are sequentially provided at the oxygen-containing gas supply pipe 232a in this order from an upstream side to a downstream side of the oxygen-containing gas supply pipe 232a in a gas flow direction.

A hydrogen-containing gas supply source 250b, an MFC 252b and a valve 253b are sequentially provided at the hydrogen-containing gas supply pipe 232b in this order from an upstream side to a downstream side of the hydrogen-containing gas supply pipe 232b in the gas flow direction. An inert gas supply source 250c, an MFC 252c and a valve 253c are sequentially provided at the inert gas supply pipe 232c in this order from an upstream side to a downstream side of the inert gas supply pipe 232c in the gas flow direction. A valve 243a is provided at the gas supply pipe 232 at a downstream side of a location where the oxygen-containing gas supply pipe 232a, the hydrogen-containing gas supply pipe 232b and the inert gas supply pipe 232c join. The valve 243a is connected to an upstream end of the gas inlet port 234.

By opening and closing the valves 253a, 253b, 253c and 243a, it is possible to adjust flow rates of the oxygen-containing gas, the hydrogen-containing gas and the inert gas by the MFCs 252a, 252b and 252c, respectively. In addition, it is configured such that process gases (that is, the oxygen-containing gas, the hydrogen-containing gas and the inert gas) are supplied into the process chamber 201 through the oxygen-containing gas supply pipe 232a, the hydrogen-containing gas supply pipe 232b and the inert gas supply pipe 232c.

A gas supplier (which is a gas supply structure or a gas supply system) according to the present embodiments is constituted mainly by the gas supply head 236 (which is constituted by the lid 233, the gas inlet port 234, the buffer chamber 237, the opening 238, the shield plate 240 and the gas outlet port 239), the oxygen-containing gas supply pipe 232a, the hydrogen-containing gas supply pipe 232b, the inert gas supply pipe 232c, the MFCs 252a, 252b and 252c, the valves 253a, 253b, 253c and 243a.

An oxygen-containing gas supplier (which is an oxygen-containing gas supply structure or an oxygen-containing gas supply system) according to the present embodiments is constituted mainly by the gas supply head 236, the oxygen-containing gas supply pipe 232a, the MFC 252a and the valves 253a and 243a. In addition, a hydrogen-containing gas supplier (which is a hydrogen-containing gas supply structure or a hydrogen-containing gas supply system) according to the present embodiments is constituted mainly by the gas supply head 236, the hydrogen-containing gas supply pipe 232b, the MFC 252b and the valves 253b and 243a. In addition, an inert gas supplier (which is an inert gas supply structure or an inert gas supply system) according to the present embodiments is constituted mainly by the gas supply head 236, the inert gas supply pipe 232c, the MFC 252c and the valves 253c and 243a.

For example, the substrate processing apparatus 10 according to the present embodiments is configured to perform an oxidation process by supplying the oxygen-containing gas through the oxygen-containing gas supplier. However, instead of the oxygen-containing gas supplier, a nitrogen-containing gas supplier (which is a nitrogen-containing gas supply structure or a nitrogen-containing gas supply system) through which a nitrogen-containing gas is supplied into the process chamber 201 may be provided. According to the substrate processing apparatus 10 provided with the nitrogen-containing gas supplier as described above, it is possible to perform a nitridation process instead of the oxidation process on the substrate (that is, the wafer W). In such a case, instead of the oxygen-containing gas supply source 250a, for example, an N₂ gas supply source serving as a nitrogen-containing gas supply source is provided, and the oxygen-containing gas supply pipe 232a is configured as a nitrogen-containing gas supply pipe.

### —Exhaust Structure—

A gas exhaust port 235 through which the reactive gas is exhausted from an inside of the process chamber 201 is provided on a lower side wall of the process vessel 203. An upstream end of a gas exhaust pipe 231 is connected to the gas exhaust port 235. An APC (Automatic Pressure Controller) valve 242 serving as a pressure regulator (pressure adjusting structure), a valve 243b serving as an opening/closing valve and a vacuum pump 246 serving as a vacuum exhaust apparatus are sequentially provided at the gas exhaust pipe 231 in this order from an upstream side to a downstream side of the gas exhaust pipe 231 in the gas flow direction. An exhaust structure (which is an exhauster or an exhaust system) according to the present embodiments is constituted mainly by the gas exhaust port 235, the gas exhaust pipe 231, the APC valve 242 and the valve 243b. The exhaust structure may further include the vacuum pump 246.

### —Plasma Generator—

The resonance coil 212 of a helical shape is provided around an outer periphery of the process chamber 201, that is, around an outer portion of a side wall of the upper vessel 210 so as to surround the process chamber 201. The resonance coil 212 serves as a first electrode. An RF (Radio Frequency) sensor 272, a high frequency power supply 273 and a matcher 274 are connected to the resonance coil 212. The matcher 274 is configured to perform an impedance matching or an output frequency matching for the high frequency power supply 273. A plasma generator (which is a plasma generating structure) according to the present embodiments is constituted mainly by the resonance coil 212, the RF sensor 272 and the matcher 274. The plasma generator may further include the high frequency power supply 273.

The high frequency power supply 273 is configured to supply the high frequency power (RF power) to the resonance coil 212. The RF sensor 272 is provided at an output side of the high frequency power supply 273. The RF sensor 272 is configured to monitor information of the traveling wave or reflected wave of the high frequency power supplied from the high frequency power supply 273. The power of the reflected wave monitored by the RF sensor 272 is input to the matcher 274, and the matcher 274 is configured to control (or adjust) an impedance of the high frequency power supply 273 or a frequency of the high frequency power output from the high frequency power supply 273 so as to minimize the reflected wave based on the information of the reflected wave input from the RF sensor 272.

The high frequency power supply 273 includes a power supply controller (which is a control circuit) (not shown) and an amplifier (which is an output circuit) (not shown). The power supply controller includes a high frequency oscillation circuit (not shown) and a preamplifier (not shown) in order to adjust an oscillation frequency and an output. The amplifier amplifies the output to a predetermined output level. The power supply controller controls the amplifier based on output conditions relating to the frequency and the power, which are set in advance through an operation panel (not shown), and the amplifier supplies a constant high frequency power to the resonance coil 212 via a transmission line.

A winding diameter, a winding pitch and the number of winding turns of the resonance coil 212 are set such that the resonance coil 212 resonates at a constant wavelength to form a standing wave of a predetermined wavelength. That is, an electrical length of the resonance coil 212 is set to an integral multiple (n times, where n is equal to or greater than 1) of a wavelength of a predetermined frequency of the high frequency power supplied from the high frequency power supply 273.

For example, a copper pipe, a copper thin plate, an aluminum pipe, an aluminum thin plate, a material obtained by depositing copper or aluminum on a polymer belt may be used as a material constituting the resonance coil 212. The resonance coil 212 is supported by a plurality of supports (not shown), which are of a flat plate shape, made of an insulating material.

### —Process Controller 221—

As shown in FIG. 2, the process controller 221 serving as the processing control structure (hereinafter, also simply referred to as a “controller 221”) is configured to control the APC valve 242, the valve 243b and the vacuum pump 246 through a signal line “A”. Further, the controller 221 is configured to control the susceptor elevator 268 through a signal line “B”, and a heater power regulator 276 and the variable impedance regulator 275 through a signal line “C”. In addition, the controller 221 is configured to control the RF sensor 272, the high frequency power supply 273 and the matcher 274 through a signal line “E”. Further, the controller 221 is configured to control the MFCs 252a, 252b and 252c and the valves 253a, 253b, 253c and 243a through a signal line “F”.

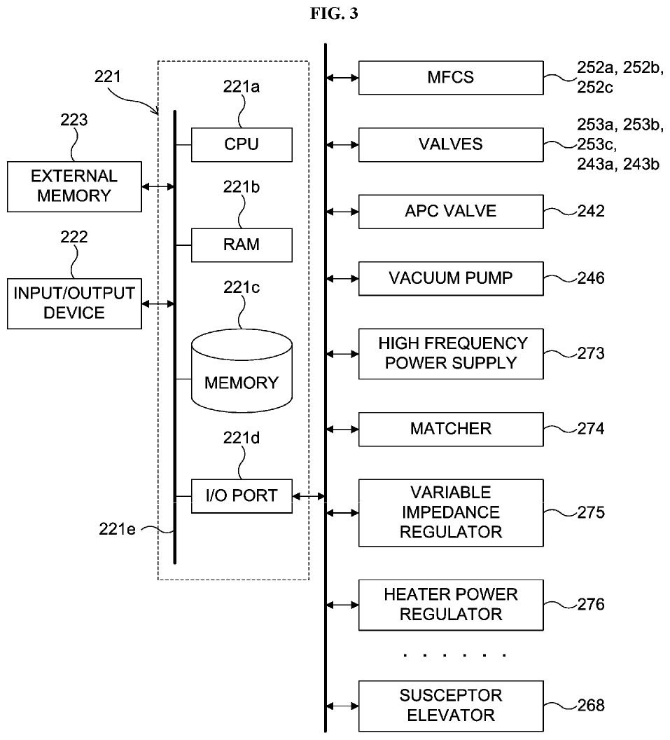

As shown in FIG. 3, the controller 221 may be constituted by a computer including a CPU (Central Processing Unit) 221a, a RAM (Random Access Memory) 221b, a memory 221c and an I/O port 221d. The RAM 221b, the memory 221c and the I/O port 221d may exchange data with the CPU 221a through an internal bus 221e. For example, an input/output device 222 constituted by components such as a touch panel and a display may be connected to the controller 221.

The memory 221c may be constituted by a component such as a flash memory and a hard disk drive (HDD). For example, data such as a control program configured to control operations of the substrate processing apparatus 10 and a program recipe in which information such as sequences and conditions of the substrate processing described later is stored may be readably stored in the memory 221c. Various program recipes such as a process recipe (processing recipe) and a chamber condition recipe serving as a pre-processing recipe described later can be obtained by combining steps of the substrate processing described later such that the process controller 221 can execute the steps to acquire a predetermined result, and functions as a program. Hereinafter, the program recipe and the control program may be collectively or individually referred to as a “program”. In the present specification, the term “program” may refer to the program recipe alone, may refer to the control program alone, or may refer to both of the program recipe and the control program. The RAM 221b functions as a memory area (work area) where a program or data read by the CPU 221a is temporarily stored.

The I/O port 221d is electrically connected to the above-described components such as the MFCs 252a, 252b and 252c, the valves 253a, 253b, 253c, 243a and 243b, the APC valve 242, the vacuum pump 246, the RF sensor 272, the high frequency power supply 273, the matcher 274, the susceptor elevator 268, the variable impedance regulator 275 and the heater power regulator 276.

The CPU 221a is configured to read and execute the control program stored in the memory 221c, and to read the process recipe stored in the memory 221c in accordance with an instruction such as an operation command inputted via the input/output device 222. The CPU 221a is configured to be capable of controlling the operations of the substrate processing apparatus 10 in accordance with the read process recipe. For example, the CPU 221a may be configured to be capable of controlling the operations such as an operation of adjusting an opening degree of the APC valve 242, an opening and closing operation of the valve 243b and a start and stop of the vacuum pump 246 via the I/O port 221d and the signal line “A”, an elevating and lowering operation of the susceptor elevator 268 via the I/O port 221d and the signal line “B”, a power supply amount adjusting operation (temperature adjusting operation) on the heater 219 by the heater power regulator 276 and an impedance adjusting operation by the variable impedance regulator 275 via the I/O port 221d and the signal line “C”, a controlling operation of the RF sensor 272, the matcher 274 and the high frequency power supply 273 via the I/O port 221d and the signal line “E”, and gas flow rate adjusting operations of the MFCs 252a, 252b and 252c and opening and closing operations of the valves 253a, 253b, 253c and 243a via the I/O port 221d and the signal line “F”.

The process controller 221 may be embodied by installing the above-described program stored in an external memory (for example, a semiconductor memory such as a USB memory and a memory card) 223 into a computer. The memory 221c and the external memory 223 may be embodied by a non-transitory computer readable recording medium. Hereafter, the memory 221c and the external memory 223 may be collectively or individually referred to as a “recording medium”. In the present specification, the term “recording medium” may refer to the memory 221c alone, may refer to the external memory 223 alone, and may refer to both of the memory 221c and the external memory 223. In addition, the program may be provided to the computer by using a communication structure such as the Internet and a dedicated line without using the external memory 223.

### Substrate Processing

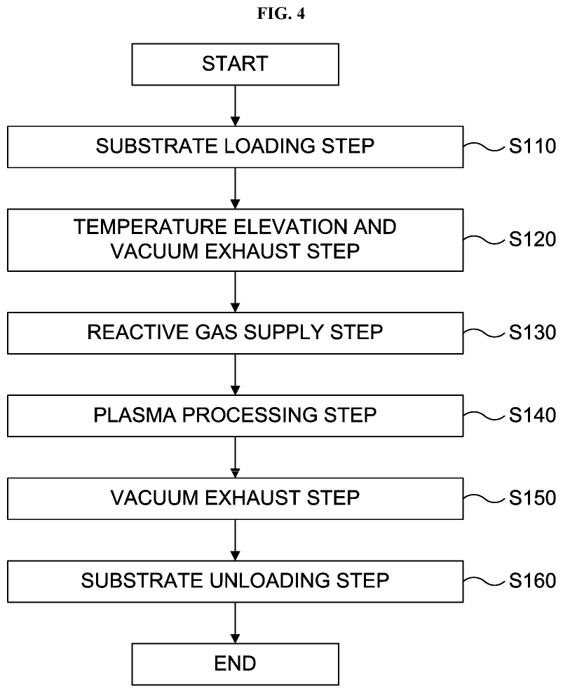

The substrate processing performed by the substrate processing apparatus 10 according to the present embodiments will be described with reference to a flow chart shown in FIG. 4. For example, the substrate processing according to the present embodiments, which is a part of a manufacturing process of a semiconductor device, is performed by the process module PM described above. In the following description, the operations of the components constituting the process module PM are controlled by the process controller 221.

### Substrate Loading Step S110

As shown by the two-dot chain line in FIG. 2, the susceptor elevator 268 lowers the susceptor 217. Then, the wafer W is supported by the pins 266 protruding from an upper surface of the susceptor 217. A step of supporting the wafer W on the pins 266 will be described in detail later.

Then, the susceptor elevator 268 elevates the susceptor 217 as shown by a solid line in FIG. 2. As a result, the lower end of the upper vessel 210 is closed by the susceptor 217 such that the process chamber 201 is provided in the upper vessel 210. As described above, the wafer W is transferred (loaded) into the process chamber 201.

### Temperature Elevation and Vacuum Exhaust Step S120

Subsequently, a temperature of the wafer W loaded into the process chamber 201 is elevated. In the step S120, the heater 219 is heated in advance, and by placing the wafer W on the susceptor 217 in which the heater 219 is embedded, the wafer W is heated to a predetermined temperature within a range from 150° C. to 750° C., for example. In the step S120, for example, the wafer W is heated such that the temperature of the wafer W reaches and is maintained at 600° C. Further, while the wafer W is being heated, the vacuum pump 246 vacuum-exhausts an inner atmosphere of the process chamber 201 through the gas exhaust pipe 231 such that an inner pressure of the process chamber 201 reaches and is maintained at a predetermined pressure. The vacuum pump 246 continuously vacuum-exhausts the inner atmosphere of the process chamber 201 at least until a substrate unloading step S160 described later is completed.

Further, in the present specification, a notation of a numerical range such as “150° C. to 750° C.” means that a lower limit and an upper limit are included in the numerical range. Therefore, for example, the numerical range “150° C. to 750° C.” means a range equal to or higher than 150° C. and equal to or lower than 750° C. The same also applies to other numerical ranges described herein.

### Reactive Gas Supply Step S130

Subsequently, as a supply of the reactive gas, a supply of the oxygen-containing gas and a supply of the hydrogen-containing gas into the process chamber 201 are started. Specifically, the valves 253a and 253b are opened to supply the oxygen-containing gas and the hydrogen-containing gas, respectively, into the process chamber 201 while flow rates of the oxygen-containing gas and the hydrogen-containing gas are adjusted by the MFCs 252a and 252b, respectively. In the reactive gas supply step S130, for example, the flow rate of the oxygen-containing gas is adjusted (or set) to a predetermined value within a range from 20 sccm to 2,000 sccm, and preferably, from 20 sccm to 1,000 sccm. In addition, for example, the flow rate of the hydrogen-containing gas is adjusted (or set) to a predetermined value within a range from 20 sccm to 1,000 sccm, and preferably, from 20 sccm to 500 sccm. More preferably, a total flow rate of the oxygen-containing gas and the hydrogen-containing gas is adjusted to 1,000 sccm, and a flow rate ratio of the oxygen-containing gas to the hydrogen-containing gas is set to be equal to or greater than 950/50. In the reactive gas supply step S130, the inner atmosphere of the process chamber 201 is exhausted by adjusting the opening degree of the APC valve 242 such that the inner pressure of the process chamber 201 reaches and is maintained at a predetermined pressure within a range from 1 Pa to 250 Pa, preferably from 50 Pa to 200 Pa, and more preferably of about 150 Pa. While appropriately exhausting the inner atmosphere of the process chamber 201 as described above, the oxygen-containing gas and the hydrogen-containing gas are continuously supplied into the process chamber 201 until a plasma processing step S140 described later is completed.

### Plasma Processing Step S140

When the inner pressure of the process chamber 201 is stabilized, the high frequency power is supplied to the resonance coil 212 from the high frequency power supply 273 via the RF sensor 272. According to the present embodiments, the high frequency power supply 273 supplies the high frequency power of 27.12 MHz to the resonance coil 212. For example, the high frequency power supplied to the resonance coil 212 is a predetermined power within a range from 100 W to 5,000 W, preferably from 100 W to 3,500 W, and more preferably of about 3,500 W. When the electric power is lower than 100 W, it is difficult to stably generate a plasma discharge.

Thereby, a high frequency electric field is formed in the plasma generation space 201a to which the oxygen-containing gas and the hydrogen-containing gas are supplied, and a donut-shaped induction plasma whose plasma density is the highest is excited by the high frequency electric field at a height corresponding to an electric midpoint of the resonance coil 212 in the plasma generation space 201a. The oxygen-containing gas and the hydrogen-containing gas are excited by the plasma and dissociate. As a result, reactive species such as oxygen radicals containing oxygen (oxygen active species), oxygen ions, hydrogen radicals containing hydrogen (hydrogen active species) and hydrogen ions may be generated.

When the electrical length of the resonance coil 212 and the wavelength of the high frequency power are the same, as described above, the donut-shaped induction plasma whose electric potential is extremely low is excited in the vicinity of the electric midpoint of the resonance coil 212 in the plasma generation space 201a. The donut-shaped induction plasma is hardly capacitively coupled with walls of the process chamber 201 or the mounting table. Since the donut-shaped induction plasma whose electric potential is extremely low is generated, it is possible to prevent a sheath from being generated on a wall of the plasma generation space 201a or on the susceptor 217. As a result, according to the present embodiments, the ions in the plasma are not accelerated.

The radicals generated by the induction plasma and non-accelerated ions are uniformly supplied onto a groove of the wafer W placed on the susceptor 217 in the substrate processing space 201b. Then, the radicals and the ions uniformly supplied onto the groove of the wafer W uniformly react with a silicon layer formed on a side wall of the groove of the wafer W. Thereby, the silicon layer is modified into a silicon oxide layer whose step coverage is good.

After a predetermined process time has elapsed (for example, 10 seconds to 300 seconds), a supply (output) of the high frequency power from the high frequency power supply 273 is stopped to stop the plasma discharge in the process chamber 201. In addition, the valves 253a and 253b are closed to stop the supply of the oxygen-containing gas and the supply of the hydrogen-containing gas into the process chamber 201. Thereby, the plasma processing step S140 is completed.

### Vacuum Exhaust Step S150

After the supply of the oxygen-containing gas and the supply of the hydrogen-containing gas are stopped, the inner atmosphere of the process chamber 201 is vacuum-exhausted through the gas exhaust pipe 231. Thereby, the gas such as the oxygen-containing gas, the hydrogen-containing gas and an exhausted gas generated by a reaction of the oxygen-containing gas and the hydrogen-containing gas in the process chamber 201 is exhausted outside of the process chamber 201. Thereafter, the opening degree of the APC valve 242 is adjusted such that the inner pressure of the process chamber 201 is adjusted to the same pressure (for example, 100 Pa) as that of a vacuum transfer chamber (which is a transfer destination of the wafer W) (not shown) provided adjacent to the process chamber 201.

### Substrate Unloading Step S160

After the inner pressure of the process chamber 201 is adjusted to a predetermined pressure, the susceptor 217 is lowered to a position of transferring the wafer W until the wafer W is supported by the pins (which are wafer lift pins) 266 (see the two-dot chain line in FIG. 2). Then, the wafer W is transferred (unloaded) out of the process chamber 201. Thereby, the substrate processing according to the present embodiments is completed. A step of unloading the processed wafer W out of the process module PM will be described in detail later.

### Main Configuration

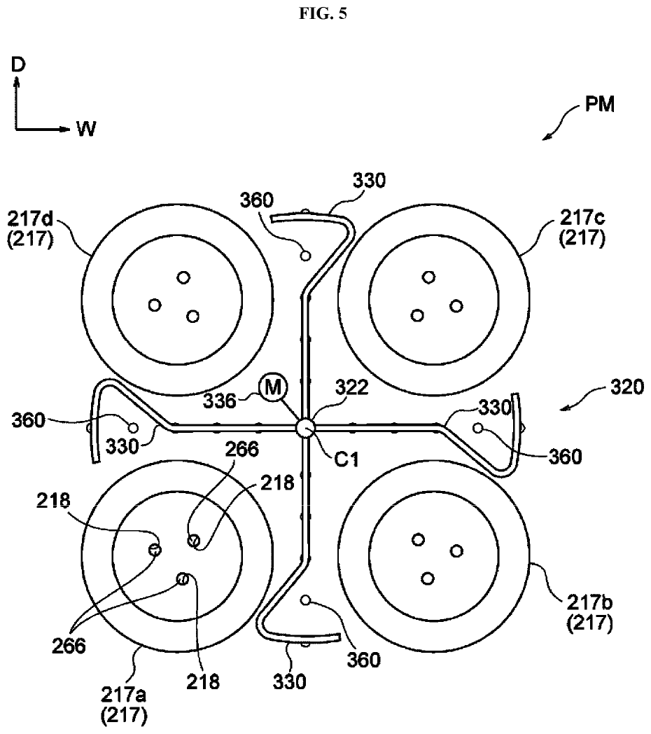

Subsequently, with reference to FIGS. 5 through 9, a configuration in which the wafer W is transferred into the process module PM and placed on each of the four susceptors 217 and a configuration in which the processed wafer W is transferred out of the process module PM will be described. Further, in each drawing, an arrow W indicates the horizontal direction which is a width direction of the process module PM, an arrow D indicates the horizontal direction which is a depth direction of the process module PM, and an arrow H indicates the vertical direction which is a up-down direction of the process module PM. The width direction, the depth direction, and the up-down direction are orthogonal to one another.

The process module PM includes the four susceptors 217, a transfer device 320 configured to transfer the wafer W loaded into the process module PM, a plurality of optical sensors 360 configured to detect the wafer W being transferred, the pins 266 described above and the transfer controller 421 configured to control the components described above.

### Susceptor 217

As shown in FIG. 5, the four susceptors 217 provided in the process module PM are arranged side by side in the width direction and the depth direction of the process module PM. Further, the four susceptors 217 are arranged around a center C1 at equal intervals. For convenience of the following description, the susceptor 217 on a front side in the depth direction and on one side in the width direction is referred to as a “susceptor 217a”, and the susceptor 217 on the other side in the width direction with respect to the susceptor 217a is referred to as a “susceptor 217b”. Further, the susceptor 217 on a back side in the depth direction and the other side in the width direction is referred to as a “susceptor 217c”, and the susceptor 217 on the one side in the width direction with respect to the susceptor 217c is referred to as a “susceptor 217d”. In addition, unless the four susceptors 217a through 217d need to be distinguished separately, the four susceptors 217a through 217d may be collectively or individually referred to as the “susceptor 217”.

Further, each susceptor 217 is provided with the through-holes 218 into which the pins 266 are inserted, respectively. The through-holes 218 are provided at three points constituting vertices of a triangle. One of the three through-holes 218 is provided at a location close to the center C1 and two of the three through-holes 218 are provided at locations away from the center C1.

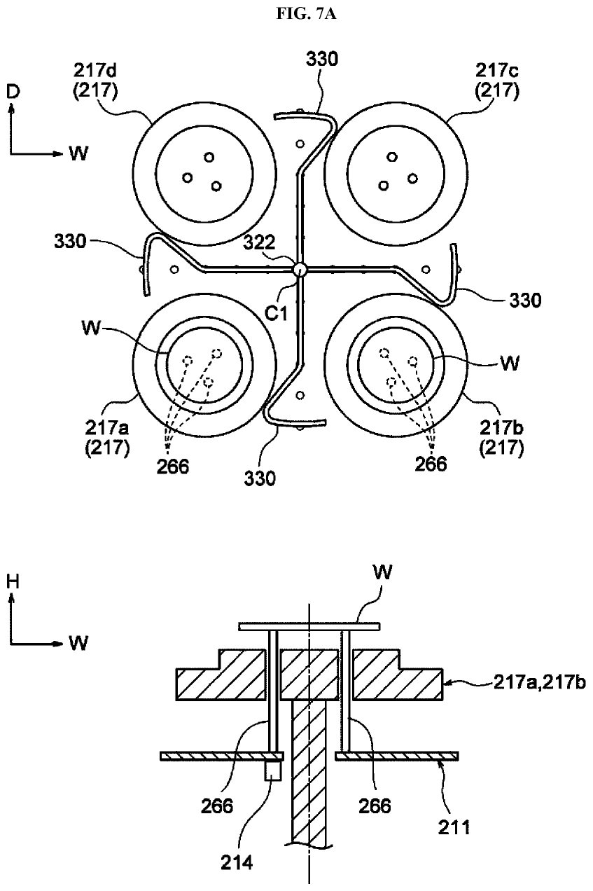

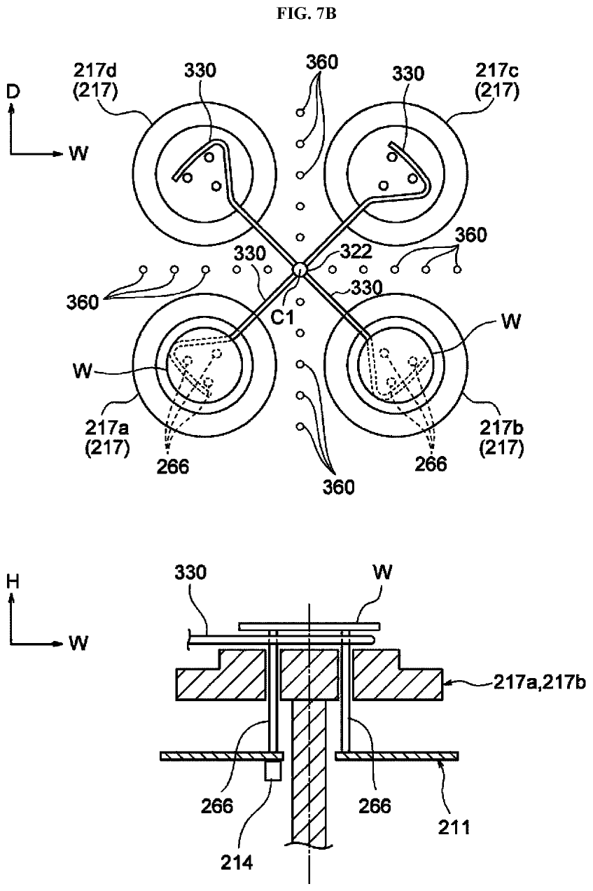

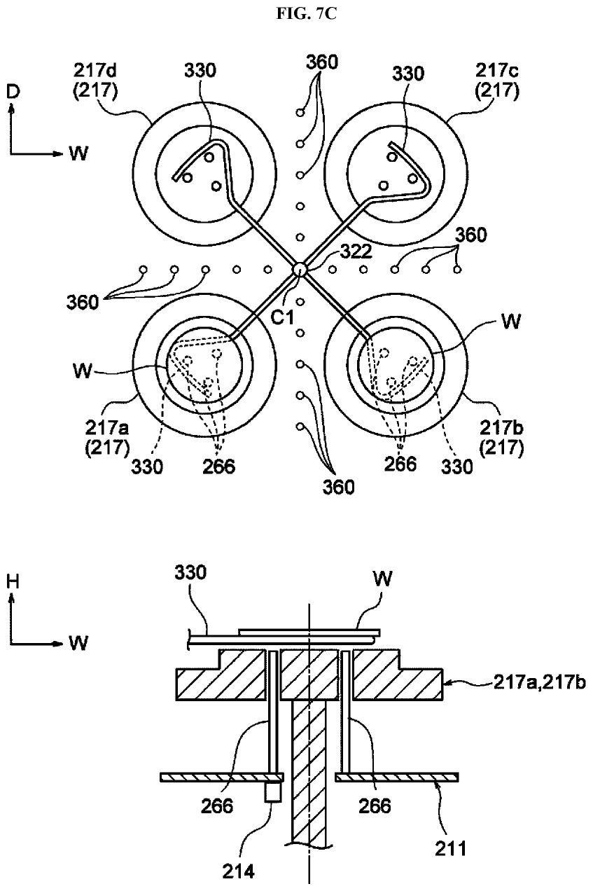

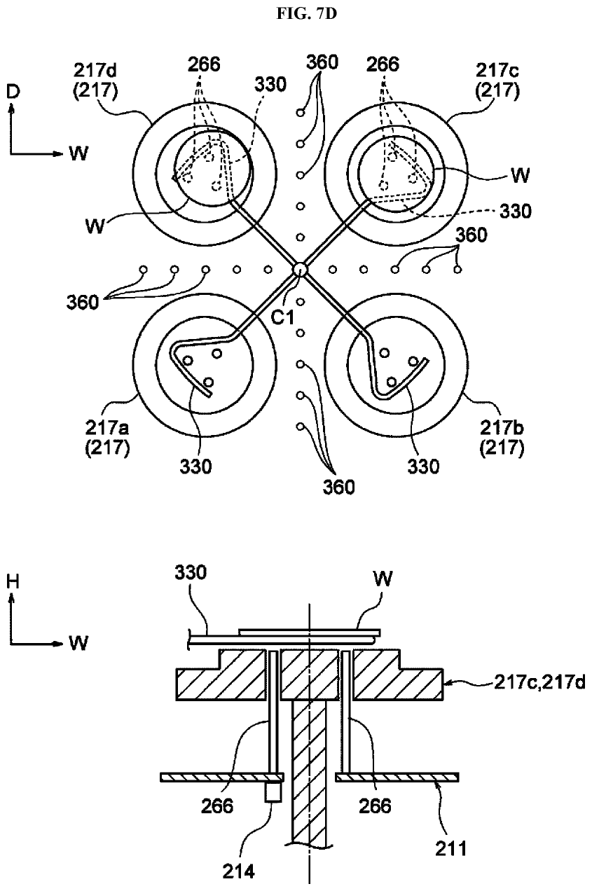

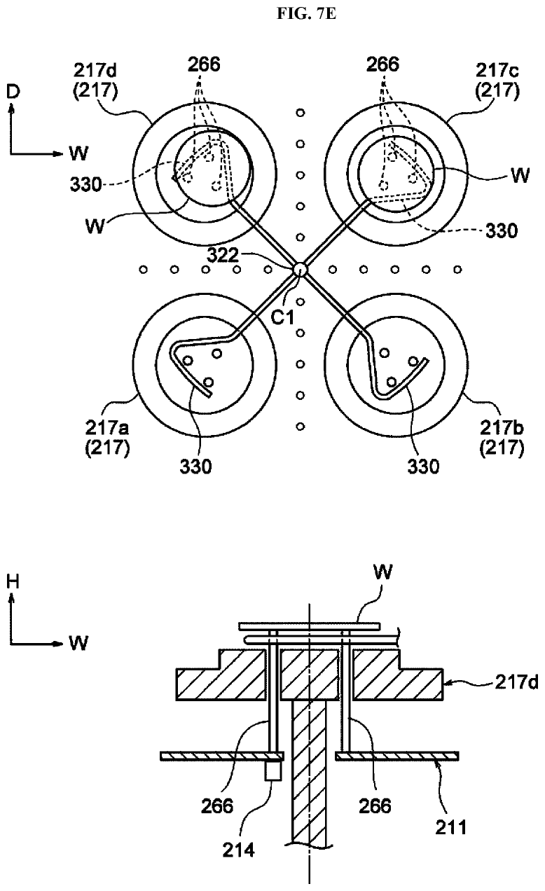

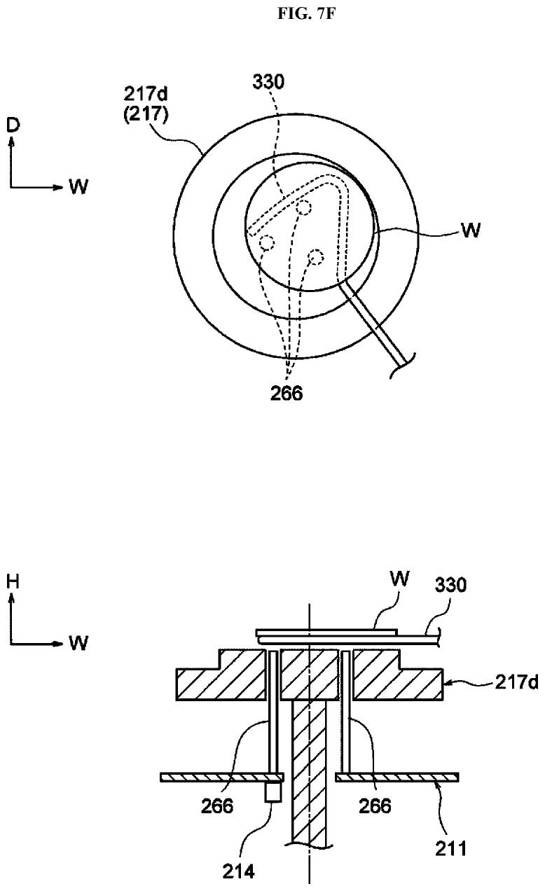

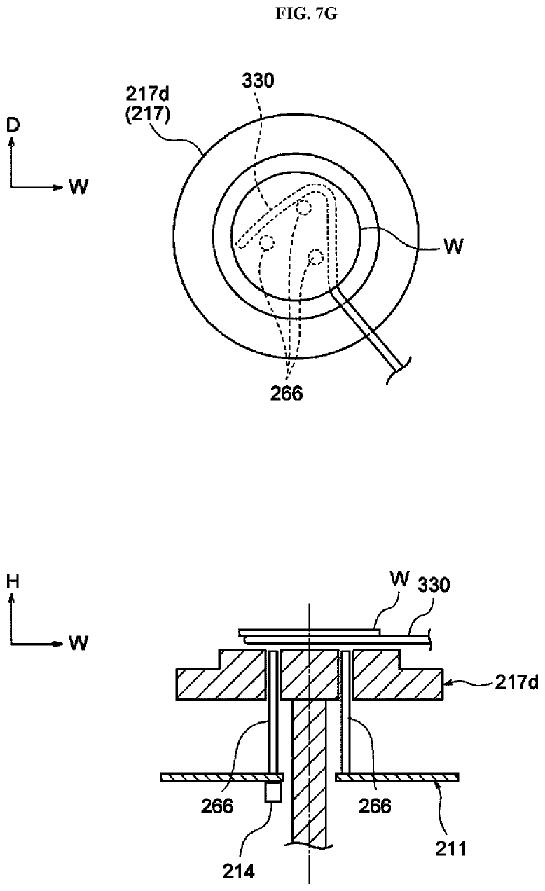

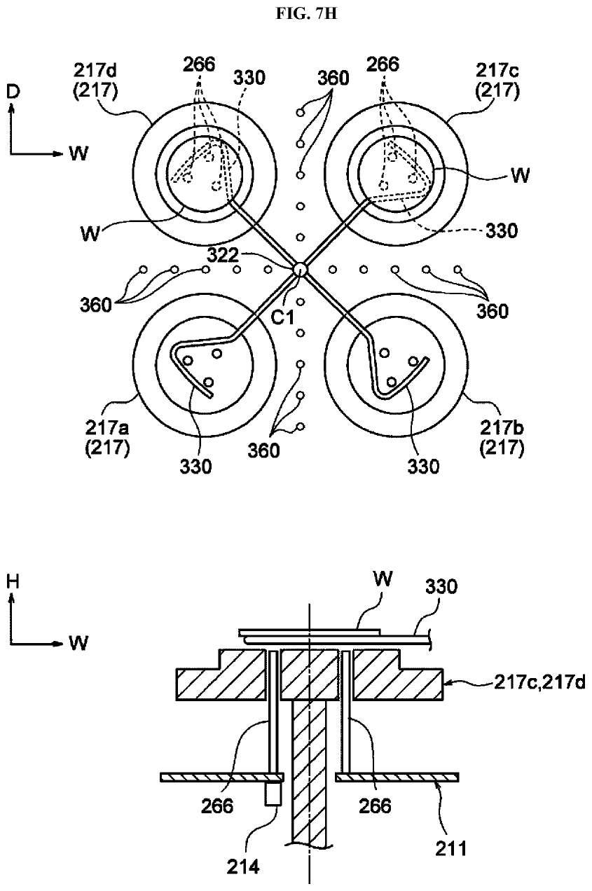

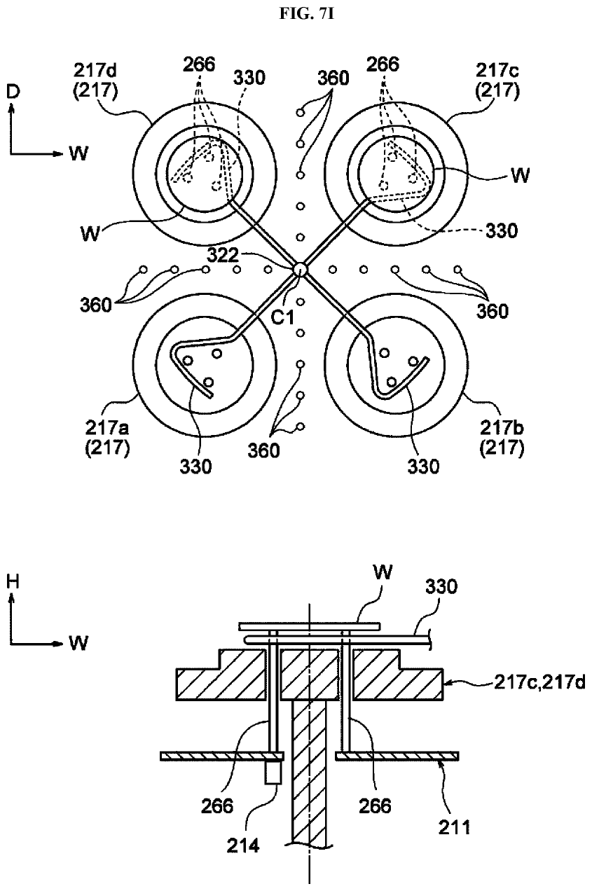

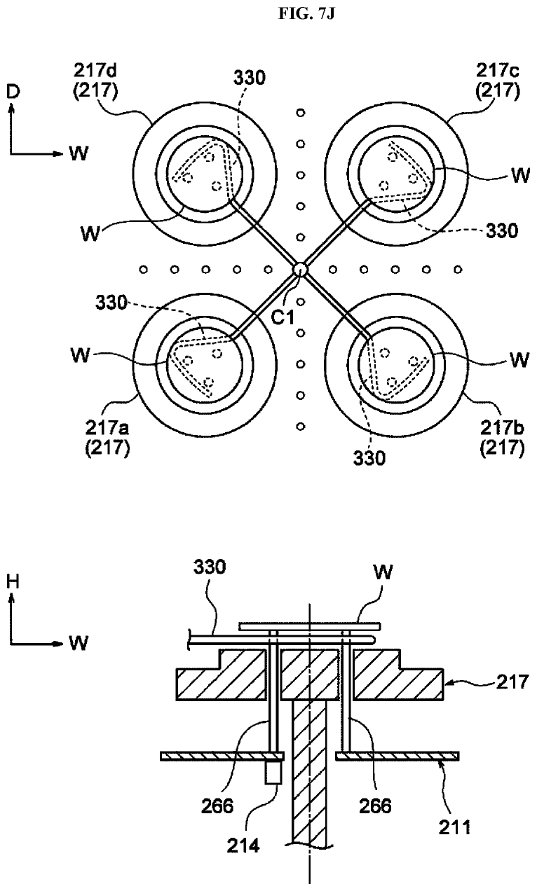

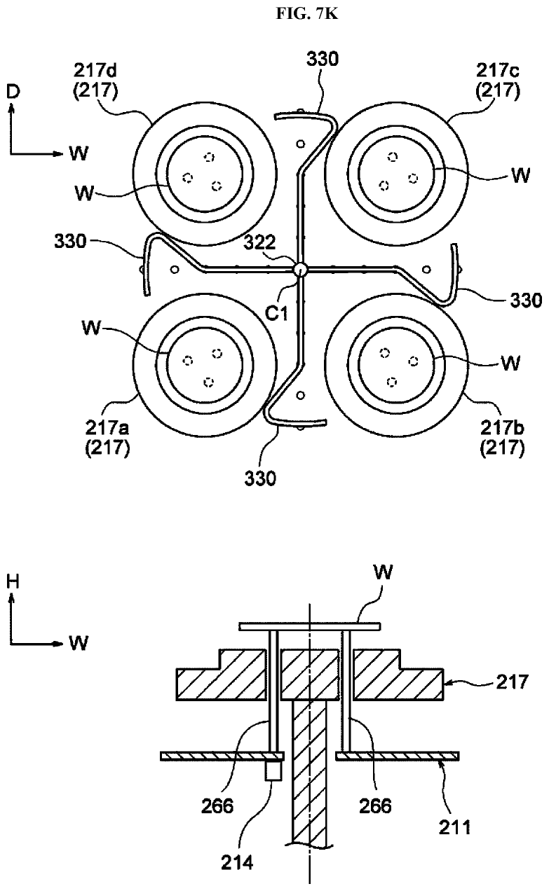

In the configuration described above, by elevating and lowering the pins 266 by the elevator 214 shown in FIG. 2, it is possible to move the pins 266 between protruding positions (see FIG. 7A) at which the pins 266 protrude from the upper surface of the susceptor 217 and storage positions (see FIG. 7C) at which the pins 266 are accommodated in the through-holes 218, respectively.

### Transfer Device 320

As shown in FIG. 5, the transfer device 320 configured to transfer the wafer W may include: a shaft 322 extending in the vertical direction; four arms 330 with a base attached to the shaft 322 and extending in the horizontal direction from the shaft 322; and a driving source 336 configured to rotate the shaft 322 in a circumferential direction. The four arms 330 are arranged at equal intervals in the circumferential direction of the shaft 322 and extend in a radial direction of the shaft 322. In the present specification, unless the four arms 330 need to be distinguished separately, the four arms 330 may be collectively or individually referred to as an “arm 330”. Further, at an initial position, the arm 330 is arranged between the adjacent susceptors 217. Further, a front end (tip) portion of the arm 330 is of a V-shape in which one portion thereof in the circumferential direction of the shaft 322 is open. As the driving source 336, for example, a stepping motor capable of controlling a rotation angle and a rotation speed by a pulse signal may be used.

In the configuration described above, the pins 266 support the wafer W as shown in FIG. 7A when the pins 266 are moved to the protruding positions. When the pins 266 support the wafer W, by rotating the arm 330 counterclockwise by 45 degrees, the arm 330 enters between the susceptor 217 and the wafer W as shown in FIG. 7B. Further, when the arm 330 enters between the susceptor 217 and the wafer W, by providing the front end (tip) portion of the arm 330 in the V-shape, the arm 330 and the pins 266 do not interfere with each other. Further, when the pins 266 are moved to the storage positions, the arm 330 supports the wafer W as shown in FIG. 7C. Then, the wafer W is transferred by rotating the arm 330 supporting the wafer W.

### Optical Sensor 360

The plurality of optical sensors 360 capable of detecting the wafer W being transferred are provided and arranged below the arm 330 in the vertical direction. In addition, the optical sensors 360 are arranged so as to partition the susceptors 217 as shown in FIG. 7B. The optical sensors 360 serve as an example of a detector. Hereinafter, the optical sensors 360 may also be collectively or individually referred to as an “optical sensor 360”.

In the configuration described above, the optical sensor 360 detects the wafer W that is transferred by the arm 330 and passes above the optical sensor 360.

### Transfer Controller 421

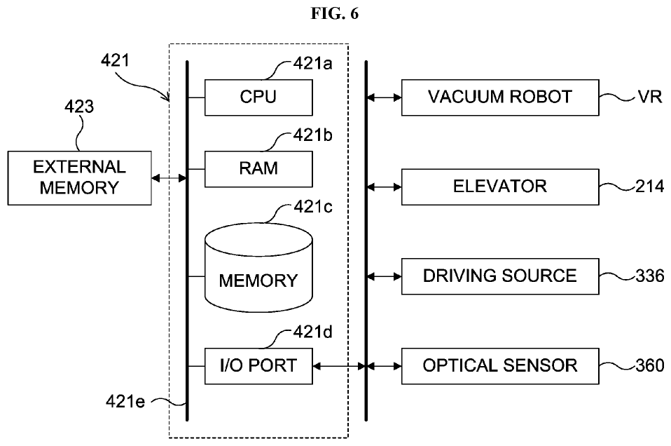

As shown in FIG. 6, through a wire communication structure (not shown) or a wireless communication structure (not shown), the transfer controller 421 is configured to control the vacuum robot VR, the elevator 214 configured to elevate and lower the pins 266, the driving source 336 configured to rotate the arm 330 and the optical sensor 360 configured to detect the wafer W being transferred.

Further, the transfer controller 421 may be constituted by a computer including a CPU (Central Processing Unit) 421a, a RAM (Random Access Memory) 421b, a memory 421c and an I/O port 421d. The RAM 421b, the memory 421c and the I/O port 421d may exchange data with the CPU 421a through an internal bus 421e.

The memory 421c may be constituted by a component such as a flash memory and a hard disk drive (HDD). For example, a transfer program configured to control operations of components such as the vacuum robot VR, the elevator 214 and the driving source 336 may be stored in the memory 421c. Further, the RAM 421b functions as a memory area (work area) where a program or data read by the CPU 421a is temporarily stored. The I/O port 421d is electrically connected to the above-described components such as the vacuum robot VR, the elevator 214, the driving source 336 and the optical sensor 360.

### Step of Placing Wafer W on Susceptor 217

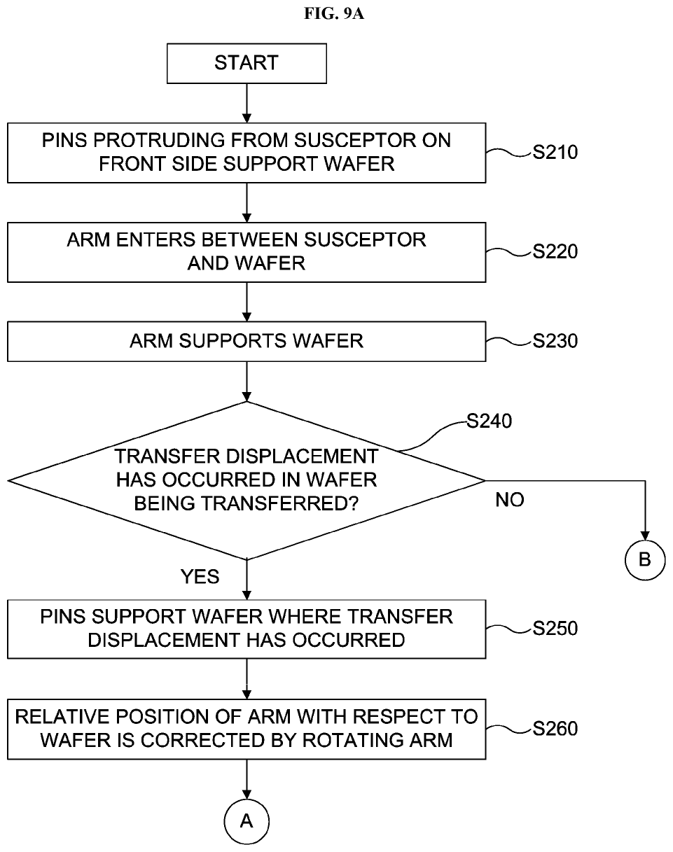

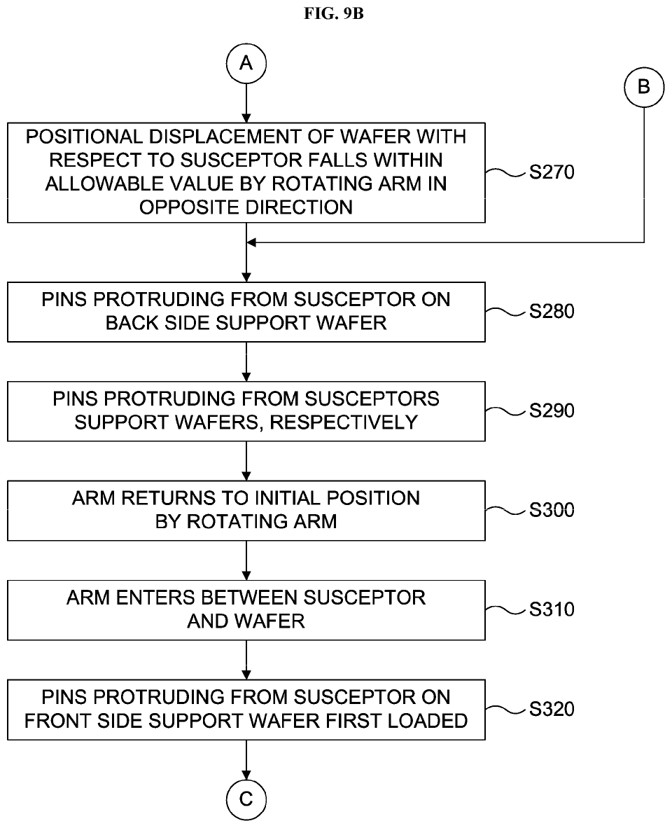

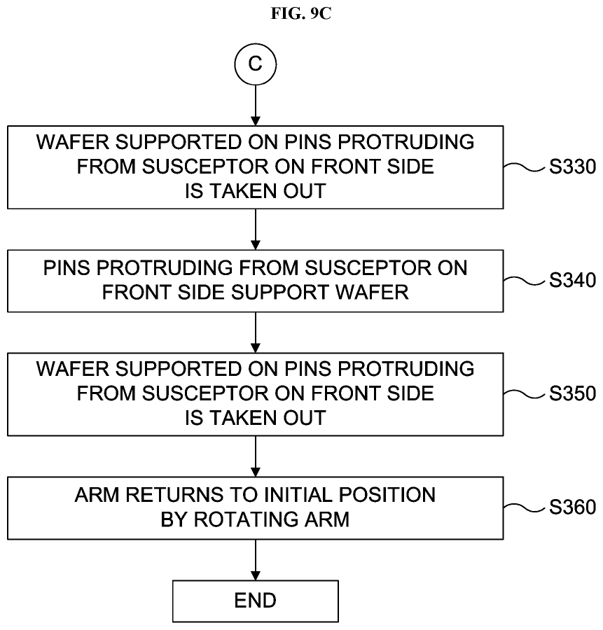

Subsequently, a step of loading the wafer W into the process module PM and placing the wafer W on each of the four susceptors 217 and the step of unloading the processed wafer W out of the process module PM will be described with reference to a flow chart shown in FIGS. 9A through 9C. The CPU 421a of the transfer controller 421 reads the transfer program stored in the RAM 421b or an external memory 423 and controls the components related thereto to perform the steps described above. The steps will be described by way of an example in which two wafers W are loaded into the process module PM, placed on two of the four susceptors 217, and unloaded out of the process module PM.

The pins 266 are arranged in the protruding positions, and as shown in FIG. 5, the arm 330 at the initial position is arranged between adjacent susceptors 217.

In such a state, in a step S210, the vacuum robot VR shown in FIG. 1 operates the arm VRA to support the two wafers W on the pins 266 protruding from the susceptor 217a and the pins 266 protruding from the susceptor 217b, respectively, as shown in FIG. 7A. In other words, the vacuum robot VR supports the two wafers W on the pins 266 protruding from each of the susceptors 217a and 217b on the front side in the depth direction, respectively. As a result, the pins 266 protruding from each of the susceptors 217a and 217b on the front side support the two wafers W. In the present embodiments, the “front side in the depth direction” refers to a portion close to the vacuum robot VR.

In a step S220, by rotating the arm 330 counterclockwise by 45 degrees, the arm 330 enters between the susceptor 217 and the wafer W (that is, between the susceptor 217a and a wafer among the two wafers W and between the susceptor 217b and the other wafer among the two wafers W) as shown in FIG. 7B.

In a step S230, by moving the pins 266 to the storage positions, the arm 330 supports the two wafers W as shown in FIG. 7C. Specifically, the arm 330 supports the two wafers W on the front side in the depth direction.

In a step S240, by rotating the arm 330 counterclockwise by 180 degrees, the arm 330 transfers the wafer W supported by the arm 330 to a location above the susceptor 217 on the back side in the depth direction as shown in FIG. 7D. Further, the optical sensor 360 detects the wafer W passing above the optical sensor 360. Specifically, the optical sensor 360 detects a timing at which the wafer W supported by the arm 330 being rotated passes above the optical sensor 360. In the present embodiments, the “timing at which the wafer W passes above the optical sensor 360” may refer to a timing at which the wafer W that has penetrated to a location above the optical sensor 360 passes above the optical sensor 360.

Further, based on a result detected by the optical sensor 360, the CPU 421a detects whether or not a transfer displacement of the wafer W has occurred due to a rotation of the arm 330. Specifically, a standard for detecting whether or not the transfer displacement of the wafer W has occurred is stored in advance in the RAM 421b, and the CPU 421a detects whether or not the transfer displacement of the wafer W has occurred based on the standard. In other words, the CPU 421a detects whether or not a relative position of the arm 330 with respect to the wafer W is deviated from the initial position, that is, whether or not the transfer displacement has occurred. Further, when the transfer displacement has occurred, the CPU 421a derives a displacement amount from the initial position of the relative position of the arm 330 with respect to the wafer W, that is, a transfer displacement amount, based on the result detected by the optical sensor 360.

When the transfer displacement of the wafer W has occurred, a step S250 is performed, and when the transfer displacement of the wafer W has not occurred, a step S280 is performed. Hereinafter, a case in which the transfer displacement of the wafer W has occurred in the wafer W transferred to a location above the susceptor 217d will be described. According to the present embodiments, for example, the transfer displacement of the wafer W has occurred in the wafer W transferred to a location above the susceptor 217d. Since the transfer displacement of the wafer W has occurred in the wafer W transferred to a location above the susceptor 217d, as shown in FIG. 7D, when viewed from above, the displacement amount between a relative position and a reference position of the wafer W with respect to the susceptor 217d, that is, a positional displacement amount of the wafer W, far exceeds an allowable value.

In the step S250, the pins 266 of the susceptor 217d above which the wafer W where the transfer displacement has occurred is transferred are moved to the protruding positions. As a result, as shown in FIG. 7E, the pins 266 protruding from the susceptor 217d support the wafer W where the transfer displacement has occurred.

In a step S260, the relative position of the arm 330 with respect to the wafer W transferred to the location above the susceptor 217d is corrected as shown in FIG. 7F by rotating the arm 330 by the transfer displacement amount in a direction in which the transfer displacement has occurred. Since the wafer W transferred to a location above the susceptor 217c is maintained while being supported by the arm 330, the relative position of the arm 330 with respect to the wafer W transferred above the susceptor 217c has not changed.

In a step S270, the arm 330 supports the wafer W on the susceptor 217d by moving the pins 266 of the susceptor 217d to the storage positions as shown in FIG. 7G. Further, by rotating the arm 330 in a direction (also referred to as an “opposite direction”) opposite to the direction in which the arm 330 is rotated in the step S260 by the transfer displacement amount, as shown in FIG. 7G, a positional displacement of the wafer W with respect to the susceptor 217d falls within the allowable value. By rotating the arm 330 in the opposite direction as described above, as shown in FIG. 7H, the positional displacement of the wafer W with respect to the susceptor 217c falls within the allowable value.

In the step S280, by moving the pins 266 of the susceptor 217c and the pins 266 of the susceptor 217d to the protruding positions, the pins 266 protruding from the susceptor 217c and the pins 266 protruding from the susceptor 217d on the back side in the depth direction support the two wafers W, as shown in FIG. 7I, respectively.

In a step S290, the vacuum robot VR shown in FIG. 1 operates the arm VRA to support other two wafers W on the pins 266 protruding from the susceptor 217a and the pins 266 protruding from the susceptor 217b, as shown in FIG. 7J. As a result, four wafers W are supported on the pins 266 protruding from the susceptor 217a, the pins 266 protruding from the susceptor 217b, the pins 266 protruding from the susceptor 217c and the pins 266 protruding from the susceptor 217d, respectively.

In a step S300, by rotating the arm 330 clockwise by 45 degrees, as shown in FIG. 7K, the arm 330 returns to the initial position.

In such a state, the susceptor 217 is moved to a closing position at which the lower end of the upper vessel 210 is closed, and the substrate processing described above is performed. Further, when the substrate processing is completed, the susceptor 217 arranged at the closing position is moved downward such that the pins 266 protrude from the susceptor 217 and the pins 266 protruding from the susceptor 217 support the processed wafer W (see FIG. 7K).

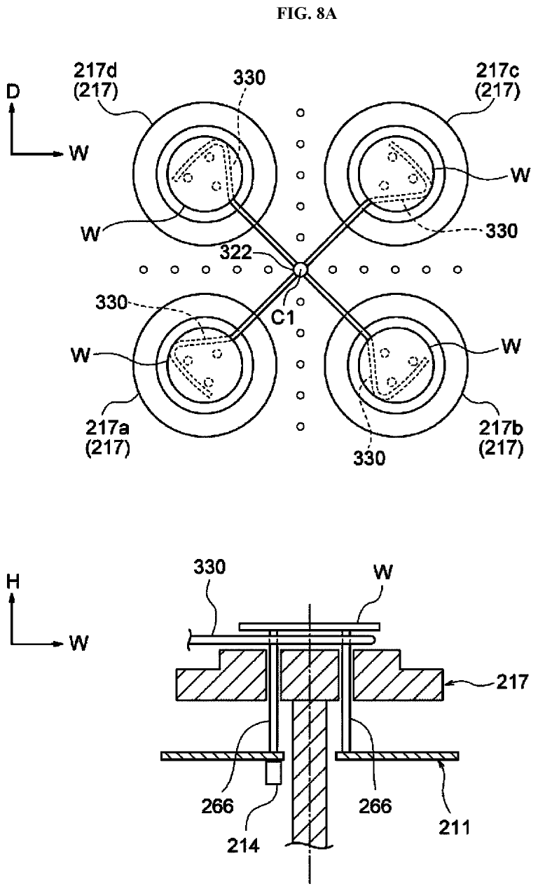

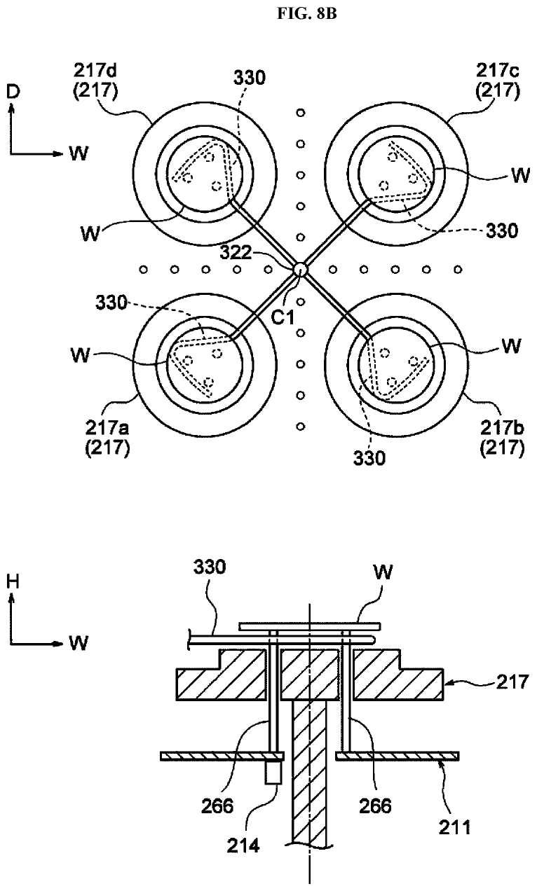

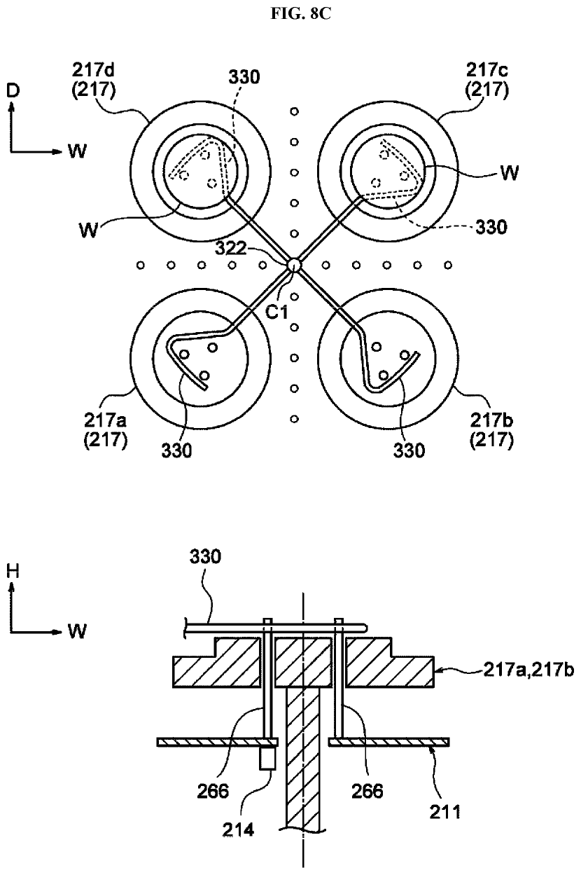

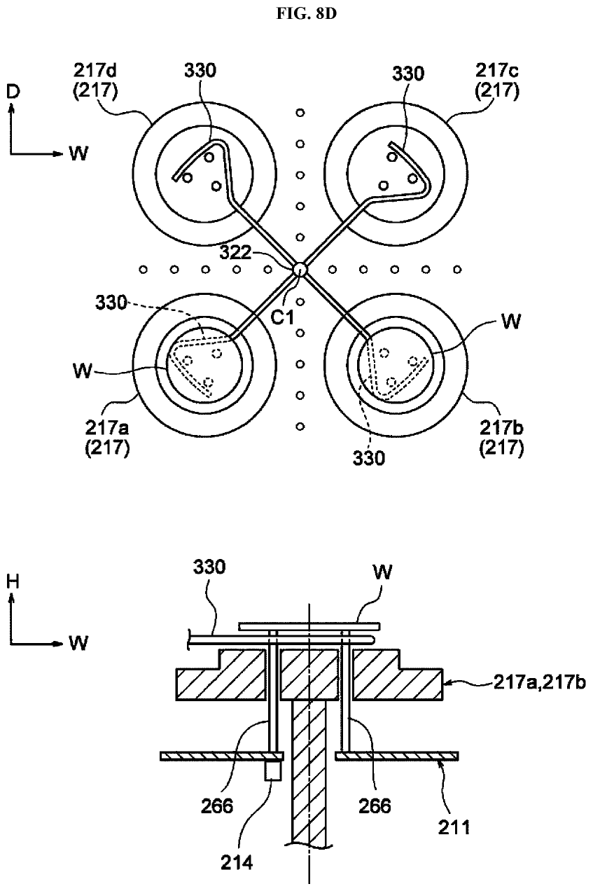

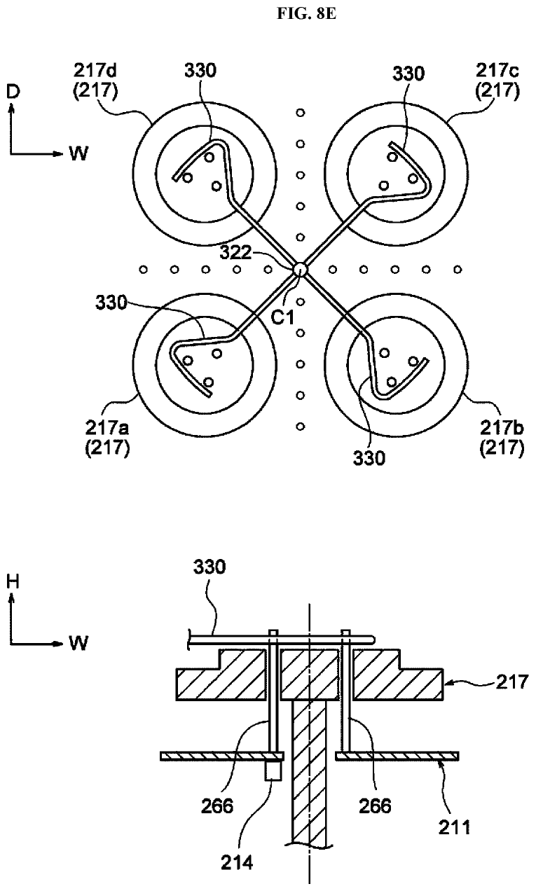

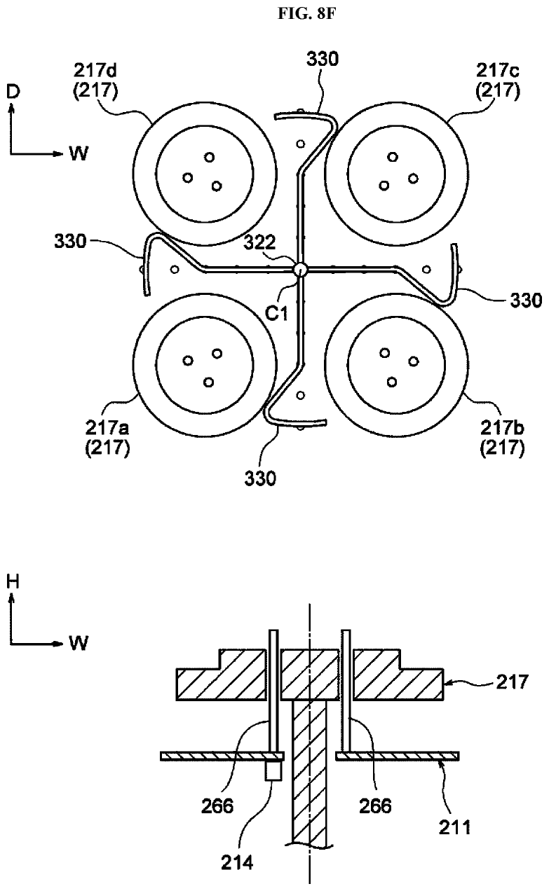

Hereinafter, the step of unloading the processed wafer W out of the process module PM will be described. In a step S310, by rotating the arm 330 counterclockwise by 45 degrees, as shown in FIG. 8A, the arm 330 enters between the susceptor 217 and the wafer W.

In a step S320, the arm 330 supports each of the wafers W by moving the pins 266 from the protruding positions to the storage positions. Further, after rotating the arm 330 counterclockwise by 180 degrees, the pins 266 at the storage positions are moved to the protruding positions. As a result, as shown in FIG. 8B, the pins 266 protruding from each of the susceptors 217a and 217b on the front side in the depth direction support the wafers W first loaded into the process module PM by the vacuum robot VR.

In a step S330, the vacuum robot VR shown in FIG. 1 operates the arm VRA to take out the wafers W supported by the pins 266 protruding from the susceptors 217a and 217b, as shown in FIG. 8C. Specifically, the wafer W supported by the pins 266 protruding from the susceptor 217a is taken out, and then the wafer W supported by the pins 266 protruding from the susceptor 217b is taken out. In other words, the wafers W supported by the pins 266 protruding from the susceptors 217a and 217b on the front side in the depth direction are sequentially taken out.

In a step S340, the pins 266 arranged at the protruding positions are moved to the storage positions. As a result, the pins 266 protruding from the susceptors 217c and 217d on the back side in the depth direction support the wafers W. Further, after rotating the arm 330 counterclockwise by 180 degrees, the pins 266 arranged at the storage positions are moved to the protruding positions. As a result, the pins 266 protruding from the susceptors 217a and 217b on the front side in the depth direction support the wafers W as shown in FIG. 8D. In the step S340, the wafers W supported by the pins 266 protruding from the susceptors 217a and 217b are the wafers W last loaded into the process module PM by the vacuum robot VR.

In a step S350, the vacuum robot VR shown in FIG. 1 operates the arm VRA to take out the wafers W supported by the pins 266 protruding from the susceptors 217a and 217b, as shown in FIG. 8E. Specifically, the wafer W supported by the pins 266 protruding from the susceptor 217a is taken out, and then the wafer W supported by the pins 266 protruding from the susceptor 217b is taken out. In other words, the wafers W supported by the pins 266 protruding from the susceptors 217a and 217b on the front side in the depth direction are sequentially taken out.

As described above, the wafers W are unloaded out of the process module PM in an order reverse to that of loading the wafers W into the process module PM. In addition, the processed wafers W unloaded out of the process module PM is returned to the carrier CA1 on the loading port structure LP1 in an order reverse that of taking out the wafers W described above.

In a step S360, by rotating the arm 330 counterclockwise by 45 degrees, the arm 330 returns to the initial position as shown in FIG. 8F. Thereby, a series of steps is completed. Further, by repeatedly performing the series of steps, the film-forming process is performed onto the plurality of wafers W.

### SUMMARY OF EMBODIMENTS

As described above, in the substrate processing apparatus 10, when the transfer displacement of the wafer W transferred by the arm 330 is detected, the pins 266 support the wafer W transferred to the location above the susceptor 217 by elevating the pins 266 so as to separate the wafer W from the arm 330. Further, after the position of the arm 330 with respect to the wafer W is corrected by rotating the arm 330 by the displacement amount, the arm 330 supports the wafer W by lowering the pins 266. Then, by rotating the arm 330 in the opposite direction by the displacement amount, the positional displacement of the wafer W with respect to the susceptor 217 is corrected. Thereby, it is possible to suppress the positional displacement of the wafer W with respect to the susceptor 217.

Further, in the substrate processing apparatus 10, by suppressing the positional displacement of the wafer W with respect to the susceptor 217, it is possible to prevent (or suppress) a uniformity of a quality of the film processed on the surface of the wafer W and a uniformity of a thickness of the film processed on the surface of the wafer W from being lowered.

Further, for example, in the substrate processing apparatus 10, the four arms 330 are provided, and by correcting the transfer displacement of the wafer W for each arm 330, it is possible to correct the positional displacement of the wafer W with respect to the susceptor 217 for each of the four arms 330. Thereby, even when a plurality of arms 330 are provided, it is possible to correct the positional displacement of the wafer W for each of the plurality of arms 330.

Further, for example, in the substrate processing apparatus 10, the four arms 330 are provided, and by correcting the transfer displacement of the wafer W for each arm 330, it is possible to correct the positional displacement of the wafer W with respect to the susceptor 217 for each of the four arms 330. Thereby, by correcting the positional displacement of the wafer W with respect to the susceptor 217 for each of the four arms 330, it is possible to minimize variations within the lot.

Further, in the substrate processing apparatus 10, the optical sensor 360 is configured to detect the timing at which the wafer W supported by the arm 330 passes through a predetermined position. As a result, the transfer controller 421 can detect the displacement amount and a displacement direction of the wafer W based on the result detected by the optical sensor 360.

### OTHER EMBODIMENTS

While the technique of the present disclosure is described in detail by way of the embodiments described above, the technique of the present disclosure is not limited thereto. It is apparent to the person skilled in the art that the technique of the present disclosure may be modified in various ways without departing from the scope thereof. For example, the embodiments described above are described by way of an example in which the plasma is used to perform the process such as the oxidation process and the nitridation process on the surface of the wafer W. However, the technique of the present disclosure is not limited thereto. For example, the technique of the present disclosure may also be applied to other processes using the plasma to process the wafer W. For example, the technique of the present disclosure may be applied to other processes using the plasma such as a modification process (or a doping process) on the film formed on the surface of the wafer W, a reduction process of an oxide film, an etching process of the film and an ashing process of a photoresist.

For example, the embodiments described above are described by way of an example in which the optical sensor 360 is used as the detector of detecting the wafer W. However, the technique of the present disclosure is not limited thereto. For example, a position of the wafer W supported by the arm 330 being rotated may be detected by an image recognition technique using a camera and an image processing device as the detector.

Further, although not particularly described in the embodiments described above, when the transfer controller 421 detects the transfer displacement of the wafer W, the vacuum robot VR may be controlled based on a detection result by the transfer controller 421 such that a position at which the wafer W is loaded into and arranged in the process module PM by the vacuum robot VR can be corrected. For example, based on the detection result indicating that the wafer W is displaced in one direction, the wafer W loaded into and arranged in the process module PM may be displaced in the other direction in advance. Thereby, it is possible to reduce a frequency of correcting the positional displacement of the wafer W in the process module PM. As a result, it is possible to reduce a workload of correcting the positional displacement of the wafer W.

Further, although not particularly described in the embodiments described above, the positional displacement of the wafer W with respect to the susceptor 217 may be corrected by correcting the transfer displacement that occurs when the processed wafer W is transferred by the arm 330. As a result, it is possible to suppress the positional displacement of the wafer W that occurs when the wafer W returns to the carrier CA1 on the loading port structure LP1.

Further, although not particularly described in the embodiments described above, a first film and a second film may be stacked on the wafer W by forming the first film on the wafer W when the wafer W is placed on one of the susceptors 217a and 217b on the front side in the depth direction and by forming the second film on the wafer W when the wafer W is placed on one of the susceptors 217c and 217d on the back side in the depth direction. In such a case, the same wafer W is transferred a plurality of times by the arm 330.

For example, the embodiments described above are described by way of an example in which the four arms 330 are provided. However, for example, one to three arms may be provided instead of the four arms 330, or five or more arms may be provided instead of the four arms 330. However, when one arm is provided, actions and effects caused by providing a plurality of arms do not occur.

For example, the embodiments described above are described by way of an example in which the relative position between the arm 330 and the wafer W is corrected by rotating the arm 330 by the displacement amount while the arm 330 and the wafer W are separated from each other. However, the relative position between the arm 330 and the wafer W may be corrected by rotating the arm 330 by the displacement amount while the wafer W is fixed.

According to some embodiments of the present disclosure, it is possible to provide the technique capable of suppressing the displacement of the substrate with respect to the mounting table when transferring the substrate by rotating the arm and placing the substrate transferred by the arm on the mounting table.

1. A substrate processing apparatus comprising:
a transfer device comprising:
a shaft configured to be rotated about a vertical direction as an axial direction; and
an arm extending in a horizontal direction from the shaft and configured to support a substrate,
wherein the transfer device is configured to transfer the substrate to a location above a mounting table by rotating the arm supporting the substrate;
a detector configured to detect a timing at which the substrate supported by the arm passes through a predetermined position;
a transfer controller configured to be capable of controlling the transfer device so as to detect a transfer displacement of the substrate with respect to the arm based on the timing detected by the detector and to correct a positional displacement of the substrate with respect to the mounting table; and
a processing structure in which a process with respect to the substrate placed on the mounting table is performed.

2. The substrate processing apparatus of claim 1, further comprises an elevator configured to elevate or lower the substrate with respect to the mounting table, and
wherein, when the transfer displacement of the substrate is detected, the transfer controller controls the transfer device and the elevator so as to perform correction of the positional displacement of the substrate with respect to the mounting table by correcting the transfer displacement by performing:
(a) elevating, by the elevator, the substrate supported by the arm and transferred above the mounting table such that the substrate is separated from the arm;
(b) correcting a position of the arm by rotating the arm after (a); and
(c) lowering the substrate by the elevator such that the substrate is supported by the arm after (b).

3. The substrate processing apparatus of claim 1, further comprising one or more arms, and
wherein the transfer controller controls the transfer device so as to perform correction of the positional displacement of the substrate with respect to the mounting table for each substrate supported and transferred by each of the arm and the one or more arms.

4. The substrate processing apparatus of claim 1,
wherein the transfer controller controls the transfer device so as to correct the positional displacement of the substrate with respect to the mounting table based on the timing detected by the detector.

5. The substrate processing apparatus of claim 1, wherein the detector is further configured to detect the substrate supported by the arm being rotated by an image recognition, and
wherein the transfer controller controls the transfer device so as to correct the positional displacement of the substrate with respect to the mounting table based on the timing detected by the detector.

6. The substrate processing apparatus of claim 1, further comprising:
an arrangement robot configured to arrange the substrate at a position where the substrate is supported by the arm, and
wherein, when the transfer displacement of the substrate is detected, the transfer controller controls the arrangement robot so as to correct a position where the substrate is arranged on the arm based on the timing detected by the detector.

7. The substrate processing apparatus of claim 1, wherein the process comprises an etching process.

8. The substrate processing apparatus of claim 1, wherein the process comprises a film-forming process.

9. A substrate processing method comprising:
(a) transferring a substrate to a location above a mounting table by rotating an arm supporting the substrate by using a transfer device comprising:
a shaft configured to be rotated about a vertical direction as an axial direction; and
an arm extending in a horizontal direction from the shaft and configured to support the substrate;
(b) detecting a timing at which the substrate supported by the arm passes through a predetermined position;
(c) detecting a transfer displacement of the substrate with respect to the arm based on the timing detected in (b) and correcting a positional displacement of the substrate with respect to the mounting table by controlling the transfer device; and
(d) performing a process with respect to the substrate placed on the mounting table.

10. The substrate processing method of claim 9, wherein the process comprises an etching process.

11. The substrate processing method of claim 9, wherein the process comprises a film-forming process.

12. A method of manufacturing a semiconductor device comprising the substrate processing method of claim 9.

13. A non-transitory computer-readable recording medium storing a program that causes, by a computer, a substrate processing apparatus to perform:
(a) transferring a substrate to a location above a mounting table by rotating an arm supporting the substrate by using a transfer device comprising:
a shaft configured to be rotated about a vertical direction as an axial direction; and
an arm extending in a horizontal direction from the shaft and configured to support the substrate;
(b) detecting a timing at which the substrate supported by the arm passes through a predetermined position;
(c) detecting a transfer displacement of the substrate with respect to the arm based on the timing in (b) and correcting a positional displacement of the substrate with respect to the mounting table by controlling the transfer device; and
(d) performing a process with respect to the substrate placed on the mounting table.

14. The non-transitory computer-readable recording medium of claim 13, wherein the program further causes the substrate processing apparatus to perform:
(e) correcting a position where the substrate is arranged on the arm, based on the timing of the detection in (b), by controlling an arrangement robot configured to arrange the substrate at a position where the substrate is supported by the arm.
